(19) United States
(12) Patent Application Publication
(10) Pub. No.: US 2005/0009476 A1
(43) Pub. Date: Jan. 13, 2005

(54) Virtual MIMO transmitters, receivers, systems and methods

(76) Inventors: Shiquan Wu, Nepean (CA); Wen Tong, Ottawa (CA); Claude Royer, Hull (CA); Peiying Zhu, Kanata (CA)

Correspondence Address: SMART & BIGGAR/FETHERSTONHAUGH & CO.;P.O. BOX 2999, STATION D, 900-55 METCALFE STREET, OTTAWA, ON, K1P5Y6, CA

(21) Appl. No.: 10/612,976

(22) Filed: Jul. 7, 2003

(51) Int. Cl. H04B 1/02; H03C 7/02; H04B 7/02; H04B 1/00

(52) U.S. Cl. 455/101; 455/129; 455/575.7

(57) ABSTRACT

A system for doing BLAST with fewer receive antennas or even only one receiving antenna is provided. A system implementation architecture is provided together with a detailed analysis on its principle and theory behind this engineering solution to reduce the MIMO technology cost by using fewer antennas whilst achieving high spectrum efficiency. Examples are provided on how to implement this idea in a CDMA platform and in a OFDM platform. For the CDMA system, the code space is automatically doubled or tripled and therefore a significant system capacity increase is realized. For OFDM systems, the throughput is doubled similar as 2×2 blasting. The system complexity is minimum and full standards backward compatibility can be achieved.

### FIELD OF THE INVENTION

The invention relates to MIMO (multiple input, multiple output) transmitters and receivers, systems and methods, and more specifically to such systems designed to have fewer antennas or only one antenna in the receiver.

### BACKGROUND OF THE INVENTION

Over the past decade, there has been a revolution in the ways in which we communicate. The Internet has created the demand for high information transfer rates, while cell phones and other mobile wireless devices have fueled the desire for ubiquitous connectivity. A significant hurdle on the road toward achieving high data rate transmission is the limit on the amount of reliable information exchange between two ends, which is known as the channel capacity C. Channel capacity is the maximum value of the so called mutual information between the transmitter and the receiver that is given by Claude Shannon's famous formula:

$$C = W log ( 1 + \frac{S}{W \times No} )$$

or a normalized version

$$C = {log}_{2} ( 1 + \frac{S}{N} ) bps \text{/} Hz \qquad ( 1 )$$

where, S is the received signal power, N=W×No is the noise power, and information is measured in bits per second per Hertz. W is the available bandwidth.

With the transmission maximum power limited and the frequency spectrum overcrowded, Shannon's expression does not seem to leave much room for increasing the information capacity. It shows a logarithmic increase in capacity as SNR (signal-to-noise ratio) increases. Roughly speaking, the channel can reliably deliver one extra bit per 5 dB SNR increase.

A careful review of Shannon's capacity formula derivation (refer to C. E. Shannon, a Mathematical theory of communication, Bell Systems Technical Journal, Vol.27, (1948), pp 379-423.) reveals that Shannon made the following three key assumptions:
1) the communication channel is point-to-point;
2) the-communication channel is memoryless; and
3) the communication channel is stationary and flat and only AWGN (additive white Gaussian noise) is present.

However, in many real wireless communication environments (i.e. channels), wireless transmissions with wavelengths of roughly 10-30 cm are readily scattered by surrounding objects such as buildings, mountains, trees, desks, cars, and so on. In the presence of such scattering objects, there are a number of paths from the transmitter to the receiver which collectively form the actual wireless communication channel. These real environments do not strictly satisfy Shannon's assumptions and therefore the question has been posed as to whether one can go beyond Shannon's capacity limit. Many researchers have claimed a ‘Yes’ answer to this question. However, the theories proposed thus far have been lacking of convincing proofs and/or are based upon a misleading assumption.

Over the past several years, multiple transmitting antennae and multiple receiving antennae systems (usually referred to as MIMO systems) have increasingly been investigated to surpass Shannon's limit. In 1996, Gerry Foschini at Bell Labs theorized that the key to beating the logarithmic nature of (1) is to exploit the scattering inherently present in the wireless communication environment [G. J. Foschini, M. Cans, on limits of wireless communications in a fading environment when using multiple antennas, Personal Communications 6, 311 (1998)]. The plurality of paths in a wireless communication environment, while appearing to only complicate matters, turns out to be a more reliable information transfer pipe. Roughly speaking, a different signal message (or a different bit stream) can be sent over each distinct path between the transmitting and receiving antenna arrays, thus increasing the information transfer rate as many times as the number of distinct channels. Foschini came up with a coding and decoding scheme, known now as BLAST (Bell Labs Space Time Architecture) that obtains these higher information-transfer rates even when the details of the scattering environment are not known to the transmitter. Generally, the idea of sending multiple distinct signals between multiple antenna arrays is known as MIMO.

To increase the information rate, M_{T} different bit streams are sent via the same physical channel from each of M_{T} transmitting antennas, respectively. The channel can be defined in frequency, time or by an orthogonal code. If the bit streams can be decoded at the receiver array, the information transfer rate can become roughly M_{T} times as large as that for single-antenna transmission with the same resource. More precisely, Shannon's capacity formula can be reproduced as

$$C = {M}_{T} log ( 1 + \frac{{M}_{R} ( S / {M}_{T} )}{N} ) bps \text{/} Hz \qquad ( 2 )$$

Note that in order to decode the M_{T} separate transmitted signals, the number of receiver antennas, M_{R}, must be at least as many as the number of transmitter antennas, M_{T} according to the state of the art of BLAST technology today. The above expression assumes that the total transmitted power is kept constant regardless of the number of transmitting antennas M_{T}. In other words, each of the M_{T} bit streams is transmitted with power S/M_{T}. Sending M_{T} different bit streams is advantageous, because it results in an increased information transfer rate by a factor of M_{T}, as compared to beam steering approaches that only increase the information transfer rate logarithmically. In fact, when the system is configured as M×1 (M transmitters transmitting the same bit stream and 1 receiver) or 1×M (1 transmitter and M receivers), the capacity formula is

$$C = log ( 1 + M \frac{S}{N} ) bps \text{/} Hz \qquad ( 3 )$$

Theoretically MIMO has a higher spectrum efficiency gain over the conventional diversity configuration. Unfortunately, this promising approach only works if the M_{T} original signals can be separated from the M_{R} received signals.

A practical case in which it does not work is when the number of receiving antennas M_{R} is significantly less than the number of transmitting antennas M_{T} or when only one receiving antenna is deployed.

Another case in which it dramatically fails is when the propagating wireless signals do not scatter off any obstacles, the so-called LOS (line-of-sight) case. The problem here is that, in some practical scenarios, all M_{R} antennas in the receiving antenna array receive essentially the same combination of the M_{T} different transmitted signals (up to a global phase shift). That is, there is little or no diversity between the M_{R} received signals. It is then extremely difficult if not impossible to distinguish the M_{T} individual transmitted signals from one another. Thus, beam steering remains the best approach in the line-of-sight case.

For the MIMO system to function properly, there is an eigen condition on the channel matrix H. The requirement is that the matrix H*H is “well conditioned”, where H* is the complex conjugate of the channel matrix H. A well conditioned matrix has full rank and has eigen values which are not extremely separated. The actual amount of separation between the eigen values that can be tolerated in a given system will be a function of the noise conditions. In the various practical scenarios mentioned above, this condition fails for the eigen values to be satisfied.

This situation can be understood by simple optics. In order for the receiver to “see” that distinct signals are being transmitted from the M_{T} distinct transmitting antennas, it must be able to resolve a geometric angle of less than α=L_{T}/d, where L_{T} is the size of the transmitting array and d is the distance between the transmitting and receiving arrays. However, if one thinks of the receiver as a lens whose aperture is its size L_{R}, its diffraction-limited angular resolution is α=λ/L_{R}, where λ is the wavelength. Thus, if λL_{R}>>L_{T}/d, which is almost always true for cell-phone systems, it is impossible for the receiver to resolve the individual transmitted signals. Another case that is well observed in the real environment is the so called “Keyhole” phenomenon that will collapse the MIMO capacity into a diversity capacity.

The presence of scattering objects in the environment effectively increases the aperture of the receiver lens that looks at the transmitting array. In other words, the scattering objects act as a large complex lens that allows the receiving array to distinguish the several different signals from a relatively small transmitter array. It is critical that, in the presence of scattering, the receiver receives power from a wide range of directions, so that the finite angular resolution of the receiver is not a limiting factor.

As a simple example consider the case shown in FIG. 1 where there are two distinct paths 14,16 from a transmitter array 10 having two antennas to a receiver array 12 having two antennas: one of the paths 14 is along the line of sight and the other path 16 bounces off a scattering object 18. Generically speaking, the outputs of the two receiving antennas in array 12 are two different linear combinations of the signals arriving from the two directions. Similarly, the signals from the two directions are two different linear combinations of the inputs to the two transmitting antennas. Thus the outputs are independent linear combinations of the inputs and can be deduced from the outputs. Therefore, if two different bit streams are sent by the transmitting antennas, the receiver will be able to recover them.

As discussed above, being able to receive two distinguishable bit streams essentially doubles the transferred information capacity. More generally, if there are M distinct paths from the transmitting to the receiving array, and there are at least M transmitters and M receivers, then the capacity may be increased M times. The maximum number of fully independent paths that can exist in a scattering environment turns out to be related to the length of time the radiation remains confined in that environment before escaping or being absorbed.

Another way to understand this capacity increase is to think in terms of phased-array techniques. With appropriately phased inputs to the transmitting antennas, the transmitter can beam steer one bit stream in one direction (along the line-of-sight path), or beam steer another bit stream in a different direction (toward the scattering object). By summing the inputs for these two cases (by the superposition principle), the transmitter will simultaneously send one bit stream along one direction and the other bit stream in the other direction. Similarly, two different combinations of the received outputs with appropriate phases will give the incoming signals from the two different directions. Thus each of the two bit streams can literally be sent over each of the two different paths and be independently received.

MIMO systems have become very attractive since the previously mention paper by Foshini defining the BLAST technique. However, MIMO systems usually need the number of receiver antennas to be greater or equal to the number of independent data transmission chains. When the number of receiving antennas is less than the number of independent data transmission chains, the MIMO service cannot always be guaranteed. This practical limitation makes it difficult to apply MIMO technology to terminal designs because one RF (radio frequency) chain contributes a significant part of the whole terminal cost, and multiple RF chains will result in too large of an expense. Particularly, most of the wireless terminals on the market, if not all of them, have a single receiving antenna which means that the MIMO technology cannot be applied to these wireless terminals including TDMA, CDMA, WCDMA, 802.11 a/b and 802.16 etc.

An example of a current transmitter and receiver for 3GPP/UMTS is shown in FIG. 2. The transmitter is generally indicated at 501 and the receiver at 503. The transmitter has two generic channels P-SCH 500 and S-SCH 502 which are not user specific. Channel P-SCH 500 undergoes gain G_{P} 510 and channel S-SCH 502 undergoes gain G_{S} 512. The two generic channels are combined in adder 514. Channels 504, 506, 508 are the channels which are sent to a specific user. There would be multiple sets of these channels for different users. Shown is the pilot channel PICH 504 and dedicated channels DDCH 1 506 . . . DDCH N 508. The pilot channel 504 is multiplied by spreading code C_{PICH} 504 and undergoes gain G_{PICH} 517. Each of the channels 506 . . . 508 is spread by a respective code C_{D1} 516 . . . , C_{DN} 518 and undergoes respective gain G_{D1} 519 . . . G_{DN} 520. Each of the user specific channels are combined at adder 522 and is scrambled by the same scrambling code at 524. The generic channels are then combined with the user specific channels at adder 526, lowpass filtered at 528 and digital-to-analog converted at 530 before being transmitted through antenna 532.

In the receiver, the receive antenna is indicated at 540. The signal received through the receive antenna 540 is converted back to digital form in ADC 542. The output of the ADC 542 is processed by synchronization block 544 which performs synchronization in both time and frequency. A frequency control output 545 is fed back to the ADC 542. The output of the synchronization block 544 is fed to finger detection block 546 which processes the synchronized signal to determine finger locations. Finger control block 548 receives the finger locations from the finger detection block 546 and controls the de-scrambling operation 550. The output of the de-scrambler 550 goes to de-spreader 552 which in turn goes to a RAKE combiner 554 which outputs soft bits for decoding indicated at 555.

In conventional OFDM (orthogonal frequency division multiplexing) systems, the subcarrier pulse used for transmission is chosen to be rectangular. This has the advantage that the task of pulse forming and modulation can be performed by a simple Inverse Discrete Fourier Transform (IDFT) which can be implemented very efficiently as an Inverse Fast Fourier Transform (IFFT). Advantageously in a receiver only a Fast Fourier Transform (FFT) operation is required to reverse this operation. According to the theorem of the Fourier transform, the rectangular pulse shape will lead to a sin(x)/x type of spectrum of the subcarriers.

The frequency spectrums of the OFDM subcarriers are not separate, but in fact they overlap. The reason why the information transmitted over the carriers can still be separated is the so-called orthogonality relationship giving the method its name. By using an IFFT for modulation the spacing of the subcarriers is implicitly chosen in such a way that at the frequency where a particular received subcarrier signal is evaluated all other received subcarrier signals are very close to zero. In order for this orthogonality to be preserved the following must be true:
a) the receiver and the transmitter must be perfectly synchronized. This means they both must assume exactly the same modulation frequency and the same time-scale for transmission;
b) the analog components, both in the transmitter and receiver, must be of very high quality; and
c) there should be no multipath channel.

To deal with the multipath channel constraint the OFDM symbols are artificially prolonged by periodically repeating the ‘tail’ of the symbol and preceding the symbol with it. At the receiver, this guard interval is removed. As long as the length of this guard interval Δ is longer than the maximum channel delay τₘₐₓ, all reflections of previous symbols are removed and the orthogonality is preserved. By preceding the useful information, of length Tᵤ, by the guard interval some parts of the signal are lost since the guard interval is not being used to transmit useful information. Taking all this into account the signal model for the OFDM transmission over a multipath channel becomes very simple: The transmitted symbols at time-slot l and subcarrier k are only disturbed by a factor H_{l,k} which is the channel transfer function (the Fourier transform of the multipath channel) at the subcarrier frequency, and by AWGN n(l,k)
z_{l,k}=α_{l,k}H_{l,k}+n(l,k) (4)
The influence of the channel can easily be removed by dividing by H_{l,k}.

The general structures of the traditional OFDM transmitter and receiver are symbolically illustrated in FIG. 3. The transmitter, generally indicated by 100, performs channel coding 104 on input bits 102, followed by symbol mapping 106. Serial-to-parallel conversion is indicated at 108. The parallel output is processed by the IFFT function 110. The output of the IFFT function is fed through a parallel-to-serial function 112. Next, the guard banding and or cyclic extension and windowing etc. are performed as indicated at 114. Digital-to-analog conversion is then performed at 116 followed by RF transmission 118 over antenna 120. Similarly, at the receiver, generally indicated at 122, processing generally follows the reverse of that which occurred in the transmitter beginning with RF reception 126 occurring via receive antenna 124. Analog-to-digital conversion 128 precedes time frequency synchronization 130. At 132, the cyclic extension is removed. Serial-to-parallel conversion 134 is followed by FFT 136, parallel-to-serial conversion 138, symbol demapping 140 and decoding 142 to produce the received bit stream 144.

### SUMMARY OF THE INVENTION

According to one broad aspect, the invention provides a transmitter comprising: N transmit antennas, where N>=2; wherein the transmitter is adapted to transmit a respective one of N transmit signals from each of the N antennas, the N transmit signals collectively containing a plurality N of main signals and a plurality of delayed main signals each delayed main signal being a delayed version of one of the main signals, wherein each transmit signal comprises a combination of a respective main signal of the plurality of main signals and at least one respective delayed main signal of the N delayed main signals.

In some embodiments, the N transmit signals comprise a Jth transmit signal Transmit_{J} from antenna J=1, . . . , N, and wherein Transmit_{J} comprises:

$${Transmit}_{J} = {α}_{J} {T}_{J} ( {S}_{J} ) + {\sum }_{i = 1}^{{K}_{J}} {α}_{i J} {T}_{i , J} ( {S}_{i J} ( t - {D}_{iJ} ) )$$

S_{J}=is the Jth main signal of the plurality of main signals; α_{J}=is a virtual spatial reflector applied to the Jth main signal; T_{J}=is a transformation applied to the Jth main signal; K_{J} is a number of delayed signals included in the Jth transmit signal; α_{iJ}=is a virtual spatial reflector applied to the ith delayed signal included in the Jth transmit signal; S_{iJ}, i=1, . . . , K_{J} are the signals which are to be delayed and included in the Jth transmit signal where each iJ ε 1, . . . , N; D_{iJ}=is a delay applied to signal S_{iJ}; T_{iJ}=is a transformation applied to the ith delayed signal included in the Jth transmit signal.

In some embodiments, each transmit signal comprises a CDMA signal.

In some embodiments, each main signal comprises a respective combined set of at least one code separated channel.

In some embodiments, each transmit signal further comprises at least one additional code separated channel not included in any main signal.

According to another broad aspect, the invention provides a transmitter for transmitting a first main signal S_{A}(t) and a second main signal S_{B}(t), the transmitter comprising: a first antenna and a second antenna; a first delay element for delaying the first main signal S_{A}(t) to produce a first delayed signal S_{A}(t-D1) where D1 is a first delay; a second delay element for delaying the second main signal S_{B}(t) to produce a second delayed signal S_{B}(t-D2) where D2 is a second delay; wherein a first linear combination of one of the main signals and one of the delayed signals is transmitted from the first antenna and a second linear combination of the other of the main signals and the other of the delayed signals is transmitted from the second antenna.

In some embodiments, the first main signal and the second main signal are each CDMA signals.

In some embodiments, the first linear combination comprises:
X_{A}(t)=α_{A1}S_{A}(t)+α_{A2}S_{A}(t-D1)
and the second linear combination comprises:
X_{B}(t)=α_{B1}S_{B}(t)+α_{B2}S_{B}(t-D2)
wherein α_{A1}, α_{A2}, α_{B1}, α_{B2} form a set of virtual spatial reflectors chosen such that a resulting channel matrix H yields a well conditioned H*H for a particular noise environment where D1 and D2 are delays.

In some embodiments, the transmitter further comprises: a scrambling circuit for scrambling a first signal to produce the first main signal and for scrambling a second signal to produce the second main signal, the first signal and the second signal being scrambled with an identical scrambling code.

In some embodiments, the transmitter further comprises: a scrambling circuit for scrambling a first signal to produce the first main signal and for scrambling a second signal to produce the second main signal, the first signal and the second signal being scrambled with different scrambling codes.

In some embodiments, each delay implemented in one of the delay elements is selected to provide enough separation between the scrambling code and a version of the scrambling code delayed by the delay such that the scrambling code and the scrambling code delayed by the delay are substantially orthogonal to each other.

In some embodiments, the transmitter further comprises: a demultiplexer for splitting a symbol stream into symbols included in said first signal and said second signal.

In some embodiments, the transmitter adapts to transmit from each antenna a respective CDMA signal containing a plurality of code separated channels, the plurality of code separated channels comprising: a respective first set of at least one channels which are generic to multiple users; a respective second set of at least one channels which are user specific; and a respective third set of channels which are user specific and which function as one of said main signals.

In some embodiments, the first main signal and the second main signal are each OFDM signals.

In some embodiments, the first linear combination comprises:
X_{A}(t)=α_{A1}S_{A}(t)+α_{B2}S_{B}(t-D1)
and the second linear combination comprises:
X_{B}(t)=α_{B1}S_{B}(t)+α_{A2}S_{A}(t-D2)
wherein α_{A1}, α_{A2}, α_{B1}, α_{B2} form a set of virtual spatial reflectors chosen such that a resulting channel matrix H yields a well conditioned H*H for a particular noise environment, where H* is the complex conjuguate of the chemical matrix H.

In some embodiments, the transmitter further comprises: a forward error correction block for performing forward error correction on an incoming bit stream to generate a coded bit stream; a symbol mapping function for mapping the coded bit stream to a first modulation symbol stream; a demultiplexing function adapted to divide the modulation symbol stream into second and third modulation symbol streams; a first IFFT function, first prefix adding function and first windowing filter adapted to process the second modulation symbol stream to generate the first main signal; a second IFFT function, second prefix adding function and second windowing filter adapted to process the third modulation symbol stream to generate the second main signal.

In some embodiments, α_{A1}, α_{A2}, α_{B1}, α_{B2} are chosen to optimize at least one of the following constraints: a) balanced energy: |α_{A1}|²+|α_{A2}|²+|α_{A1}+α_{A2}|²=|α_{B1}|²+|α_{B2}|²+|α_{B1}+α_{B2}|²; b) there is no large notch in frequency domain; c) maximize capacity; and d) meet a specified spectrum mask.

According to another broad aspect, the invention provides a receiver for receiving a signal transmitted over a wireless channel from a transmitter having a plurality N of transmit antennas, wherein the transmitter is adapted to transmit a respective one of N transmit signals from each of the N antennas, the N transmit signals collectively containing a plurality N of main signals and a plurality of delayed main signals each delayed main signal being a delayed version of one of the main signals, wherein each transmit signal comprises a combination of a respective main signal of the plurality of main signals and at least one respective delayed main signal of the N delayed main signals, the receiver comprising: at least one receive antenna, each receive antenna receiving a respective receive signal over the wireless channel from the transmitter; receive signal processing circuitry adapted to perform receive processing for each of the N main signals and each of the N delayed main signals.

In some embodiments, there are less than N receive antennas.

In some embodiments, there is only one receive antenna.

In some embodiments, all signals are CDMA signals.

In some embodiments, the receive signal processing circuitry comprises: a finger detector configured to process each receive signal to identify multi-path components transmitted by each antenna, the multi-path components comprising at least one pair of multi-path components comprising a first multi-path component and a second multi-path component which is later than the first multi-path component by the delay introduced at the transmitter.

In some embodiments, the receive signal processing circuitry comprises de-scrambling and de-spreading functions which produce de-spread signals for each multi-path component, the receiver further comprising: a virtual array processor for performing combining of the de-spread signals.

According to another broad aspect, the invention provides a receiver for receiving a signal transmitted over a wireless channel from a transmitter having a plurality N of transmit antennas, wherein the transmitter is adapted to transmit a respective one of N transmit signals from each of the N antennas, the N transmit signals collectively containing a plurality N of main signals and a plurality of delayed main signals each delayed main signal being a delayed version of one of the main signals, wherein each transmit signal comprises a combination of a respective main signal of the plurality of main signals and at least one respective delayed main signal of the N delayed main signals, the receiver comprising: at least one receive antenna, each receive antenna receiving a respective receive signal over the wireless channel from the transmitter; for each receive antenna, a respective over-sampling analog to digital converter which samples the respective receive signal and a respective sample selector adapted to produce a respective plurality of sample streams; signal processing circuitry adapted to perform receive processing for each of the sample streams to produce pre-combined signals; a MIMO decoder adapted to perform MIMO processing on the pre-combined signals.

In some embodiments, each transmit signal comprises a main signal and N-1 delayed signals, and wherein each over-sampling analog to digital converter performs N times over-sampling.

In some embodiments, each transmit signal comprises one main signal and one delayed main signal, wherein two-times over-sampling is performed, and wherein the sample selector takes all even samples to generate a first of the sample streams, and takes all odd samples to generate a second of the sample streams.

According to another broad aspect, the invention provides a system comprising: a transmitter; a receiver comprising: at least one receive antenna, each receive antenna receiving a respective receive signal over the wireless channel from the transmitter; receive signal processing circuitry adapted to process the receive signals.

In some embodiments, the receive signal processing circuitry is adapted to perform receive processing for each of the N main signals and each of the N delayed main signals.

In some embodiments, the system adapts to transmit and receive CDMA signals.

In some embodiments, each main signal comprises a respective combined set of at least one code separated channel.

In some embodiments, there are two transmit signals, and the main signals comprise a first main signal S_{A}(t) and a second main signal S_{B}(t), the transmitter further comprising: a first antenna and a second antenna; a first delay element for delaying the first main signal S_{A}(t) to produce a first delayed signal S_{A}(t-D1) where D1 is a first delay; a second delay element for delaying the second main signal S_{B}(t) to produce a second delayed signal S_{B}(t-D2) where D2 is a second delay; wherein a first linear combination of one of the main signals and one of the delayed signals is transmitted from the first antenna and a second linear combination of the other of the main signals and the other of the delayed signals is transmitted from the second antenna.

In some embodiments, the receive signal processing circuitry comprises: a finger detector configured to process each receive signal to identify multi-path components transmitted by each antenna, the multi-path components comprising at least one pair of multi-path components comprising a first multi-path component and a second multi-path component which is later than the first multi-path component by the delay introduced at the transmitter.

In some embodiments, the receive signal processing circuitry comprises de-scrambling and de-spreading functions which produce de-spread signals for each multi-path component the receiver further comprising: a virtual array processor for performing combining of the de-spread signals.

In some embodiments, the system adapts to transmit and receive OFDM signals.

In some embodiments, the system adapts to transmit and receive OFDM signals wherein the transmitter further comprises: a forward error correction block for performing forward error correction on an incoming bit stream to generate a coded bit stream; a symbol mapping function for mapping the coded bit stream to a first modulation symbol stream; a demultiplexing function adapted to divide the modulation symbol stream into second and third modulation symbol streams; a first IFFT function, first prefix adding function and first windowing filter adapted to process the second modulation symbol stream to generate the first main signal; a second IFFT function, second prefix adding function and second windowing filter adapted to process the third modulation symbol stream to generate the second main signal.

In some embodiments, the receiver comprises: at least one receive antenna, each receive antenna receiving a respective receive signal over the wireless channel from the transmitter; for each receive antenna, a respective over-sampling analog to digital converter which samples the respective signal and a respective sample selector adapted to produce a respective plurality of sample streams; signal processing circuitry adapted to perform receive processing for each of the sample streams to produce pre-combined signals; a MIMO decoder adapted to perform MIMO processing on the pre-combined signals.

In some embodiments, each transmit signal comprises a main signal and N-1 delayed signals, and wherein each over-sampling analog to digital converter performs N times over-sampling.

In some embodiments, each transmit signal comprises one main signal and one delayed main signal, wherein two-times over-sampling is performed, and wherein the sample selector takes all even samples to generate a first of the sample streams, and takes all odd samples to generate a second of sample streams.

According to another broad aspect, the invention provides a method of transmitting comprising: delaying each of N main signals by each of at least one respective delay to produce at least one respective delayed main signal; transmitting from each of N>=2 antennas a respective signal comprising one of the main signals combined with at least one of the delayed main signals.

According to another broad aspect, the invention provides a method of receiving comprising: at a single receive antenna, receiving over a wireless channel a received signal produced in accordance with one of the above methods; processing the received signal to produce at least two signals which are mathematically equivalent to two signals-which would be received over two different receive antennas; processing the two signals as if they were received over two different antennas.

### BRIEF DESCRIPTION OF THE DRAWINGS

Preferred embodiments of the invention will now be described with reference to the attached drawings in which:

FIG. 1 is a schematic illustration of typical communication link existing in a scattering environment;

FIG. 2 is a block diagram of a typical conventional typical CDMA (Code Division Multiple Access) transmitter;

FIG. 3 is a block diagram of a traditional OFDM (orthogonal Frequency Division Modulation) transceiver;

FIG. 4A is a schematic of a downlink transmitter for a CDMA based transmitter provided by an embodiment of the invention;

FIG. 4B is a block diagram of a generic spatial reflector function provided by an embodiment of the invention;

FIG. 4C is a block diagram of a CDMA transmitter similar to that of FIG. 2, but adapted to employ the spatial reflector function of FIG. 4B, in accordance with an embodiment of the invention;

FIG. 5 is schematic of a downlink transmitter for a CDMA based transmitter provided by another embodiment of the invention;

FIG. 6 is a schematic of a CDMA receiver provided by an embodiment of the invention, for use with the embodiment of FIG. 4;

FIG. 7 is a code tree to demonstrate that using the CDMA embodiment of FIG. 4 or 5 enlarges the code space over traditional CDMA;

FIG. 8 is a block diagram of an OFDM based transmitter provided by an embodiment of the invention;

FIG. 9 is a block diagram of another OFDM based transmitter provided by another embodiment of the invention;

FIG. 10A is a plot of the impulse response sampling of a rectangular channel;

FIG. 10B is a plot of the impulse response sampling of a channel Ch_{A}(t)=rect(t)+rec(t-T/2) for use with some embodiments of the invention;

FIG. 10C is a plot of the impulse response sampling of a channel Ch_{B}(t)=rect(t)−2rect(t-T/2) for use with some embodiments of the invention;

FIG. 11 is a schematic illustration of a communication link consisting of a transmitter section and a virtual spatial antenna configuration representing a single receiver antenna, as provided by an embodiment of the invention;

FIG. 12 is a block diagram of an OFDM virtual antenna receiver provided by an embodiment of the invention, useable with the transmitters of FIGS. 6 and 7;

FIG. 13 is a schematic illustration of the keyhole phenomenon as it relates to a communication link;

FIG. 14 is a block diagram of an embodiment of the invention employing two receive antennas; and

FIG. 15 shows simulated performance results in terms of SNR (Signal-To-Noise) versus BER (Bit-Error-Rate) for QSPK and QAM-16 modulation techniques of various BLAST, and STTD (Space-Time Transmit Diversity) transmission schemes, and for embodiments of the invention.

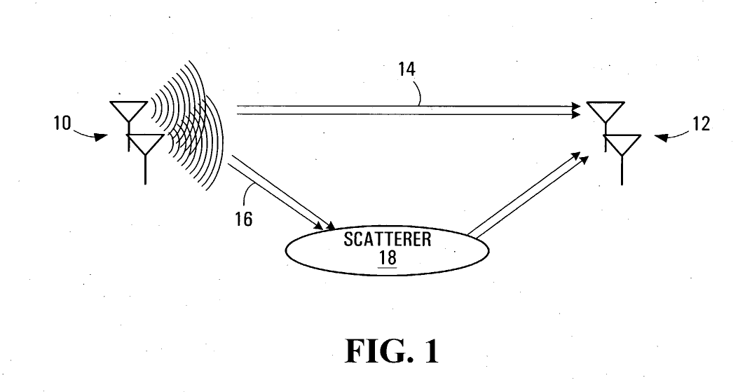

### DETAILED DESCRIPTION OF THE PREFERRED EMBODIMENTS

Channel Interception via Designed Reflectors

According to an embodiment of the invention, a method, herein referred to as “channel interception” is provided which pre-sets a propagation environment either in a deterministic way or quasi-random way to guarantee a satisfactory MIMO (Multiple Input Multiple Output) eigen condition of the channel matrix H.

The propagation environment adds further channel variations on top of the pre-set environment but the pre-set environment will exist even if the random environment causes a destruction of the MIMO channel structure. It is noted that the conventional pre-distortion concept and constellation rotation concept may be considered types of channel interception. Both these conventional techniques use channel impulse response information (usually by feedback) and reverse the channel before transmission in order to cancel the multipath effect in the receiver end.

In contrast, the channel interception provided in this embodiment of the invention, rather than attempting to remove the multipath effect, intentionally creates a multipath effect. The basic concept is to form a set of wave reflectors in baseband before transmission so that the received channel matrix favours MIMO transmission. Using this method, the MIMO channel can always be setup whether the channel is scattering or not.

Furthermore, it has been noted above that with conventional MIMO applications, MIMO needs more than one receiver antenna and this proves to be a very stringent requirement for conventional mobile terminals which typically only have one receiver RF chain. To add another RF chain almost doubles the mobile terminal cost and increases power consumption significantly. With the channel interception technology provided by the invention, one receiving antenna is enough in most applications to receive and then to distinguish the multiple transmitted data streams.

The invention has very general applications. Two very specific implementations will be presented, namely CDMA (Code Division Multiple Access) and OFDM (Orthogonal Frequency Division Modulation) implementations. The very specific examples will involve two transmit antennas and one receive antenna. However, it is to be understood that larger numbers of transmit antennas can be employed in alternative embodiments. Furthermore, additional receive antennas can be employed. Each receive antenna in such an application will behave as if it were multiple receive antennas. In the case of multiple receive antennas, ‘virtual antennas’ provided by the invention can be used together with the physical antennas to form an enlarged antenna array.

CDMA Embodiment

This embodiment of the invention provides a system and method for performing parallel transmission (or BLAST) with only one receiving antenna in a CDMA context. For this very specific example, the 3GPP/UMTS standard is assumed as an example but the concept is very generic and can be applied to other systems such as, but not limited to, CDMA2000 or TD-SCDMA or even GSM.

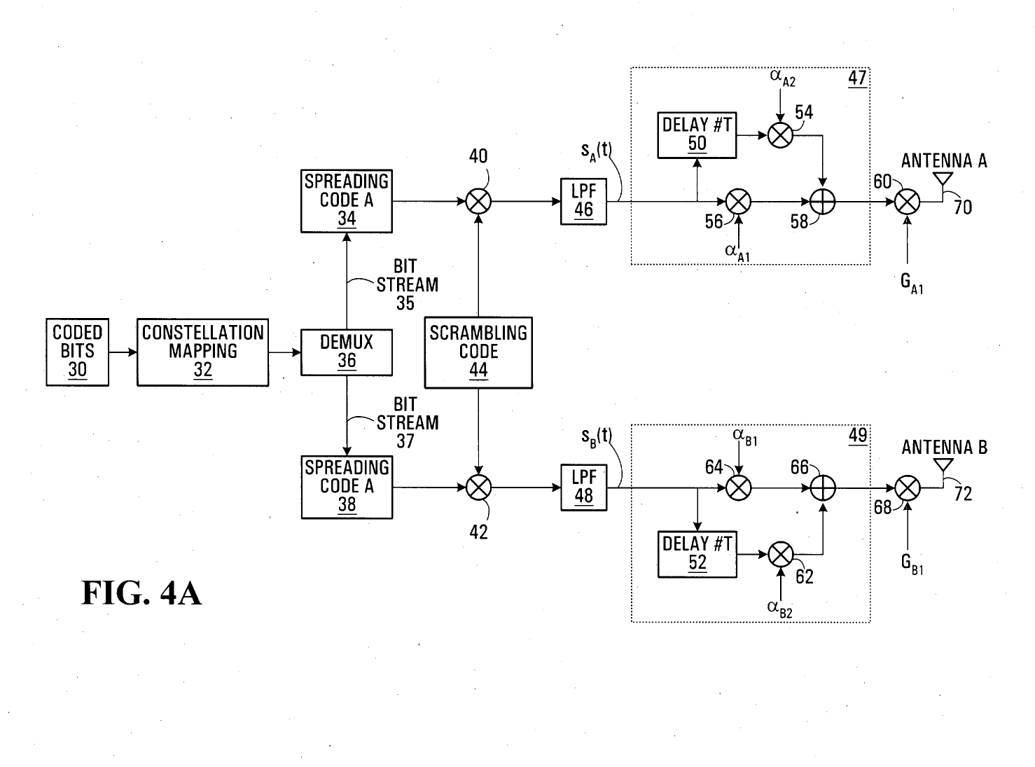

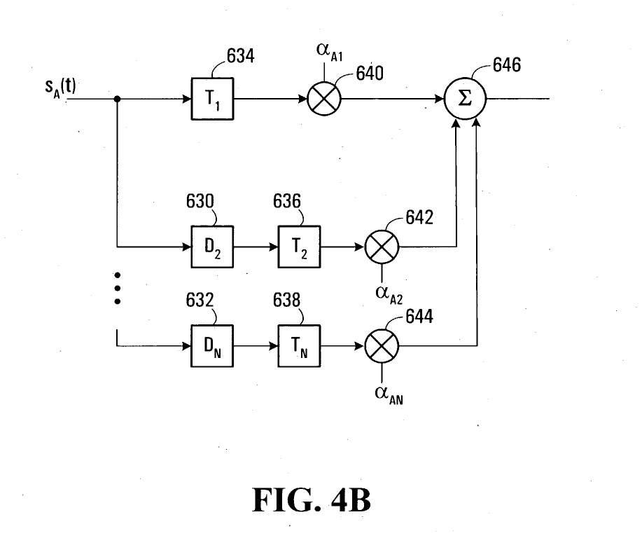

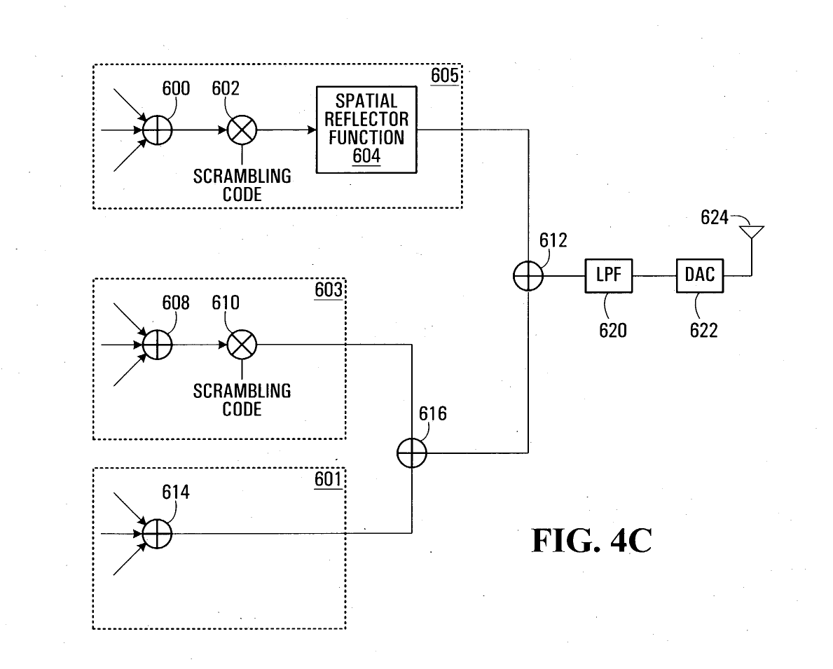

FIG. 4A illustrates the main transmitter baseband processing blocks for an example implementation. In the diagram, the coded bits 30 are first mapped to constellation symbols with constellation mapping 32, and the symbol sequence is de-muxed with demultiplexer 36 into two parallel streams which are output at 35 and 37. More generally, any number of parallel streams may be generated at this point. Each data stream, say the upper output 35, is first spread and scrambled. More specifically, for the upper output 35, spreading code A 34 is applied, and the output of this is multiplied with a scrambling code 44 in multiplier 40. Similar processing for output 37 is applied with spreading code A 38 and multiplier 42. Scrambling occurs at the chip rate. A low pass filtering operation, for example using a RRC (Root Raised Cosine) filter, indicated at 46,48 is applied to the outputs of the two multipliers 40,42. This might for example realize a shaping filter function and an interpolation filter function to convert the chip level data into a quantized signal suitable for Digital-to-Analog Conversion (DAC). Up conversion will start after applying the channel Gain GA1 and GB1 and combining with other channels such as a pilot channel and/or other data channels if present.

The output of the first lowpass filter 46 is signal s_{A}(t), while the output of the second lowpass filter 48 is signal s_{B}(t). The signal s_{A}(t) is processed by functional block 47 whose purpose is to process the signal such that single antenna reception can be performed as described below. Similarly, the signal s_{B}(t) is processed by functional block 49.

In functional block 47, signal s_{A}(t) is multiplied by a virtual spatial reflector α_{A1} 56. The signal s_{A}(t) is also delayed in delay block 50, and then multiplied by a second virtual spatial reflector α_{A2} 54. The outputs of the two virtual reflectors 54,56 are combined in adder 58. A channel gain G_{A1} is applied at 60 and the data stream is then combined with other users channels or common signaling channels such as pilot channel (PICH) or primary synchronization channel (PSCH) etc., and is transmitted via antenna A 70.

Similarly, in functional block 49, the signal S_{B}(t) is multiplied by a virtual spatial reflector α_{B1} 64. The signal s_{B}(t) is also delayed in delay block 52, and then multiplied by a second virtual spatial reflector α_{B2} 62. The outputs of the two virtual reflectors 62,64 are combined in adder 66. A channel gain G_{B1} is applied at 68 and the data stream is then combined with other users channels or common signaling channels such as pilot channel (PICH) etc., and is transmitted via antenna B 72.

Note that the reflectors α_{A1}, α_{A2}, α_{B1}, α_{B2} and the delay introduced in delay blocks 50,52 are design parameters. In some embodiments, the reflectors are constant over time and might be complex numbers for example. In other embodiments, the reflectors are functions of time. For example, in one embodiment the reflectors are pseudo-random functions of time. When this is the case, the reflectors still need to satisfy the constraints introduced below at any given instant. Preferably the reflectors will have a unit gain and will result in a balanced power dissipation and balanced eigen values of the matrix defined by the following:

$$\begin{matrix}H * H = {[ \begin{matrix}{α}_{A1} & {α}_{B1} \\ {α}_{A2} & {α}_{B2}\end{matrix} ]}^{*} [ \begin{matrix}{α}_{A1} & {α}_{B1} \\ {α}_{A2} & {α}_{B2}\end{matrix} ] \\ = [ \begin{matrix}{\vert {α}_{A1} \vert}^{2} + {\vert {α}_{A2} \vert}^{2} & conj ( {α}_{A1} ) {α}_{B1} + conj ( {α}_{A2} ) {α}_{B2} \\ conj ( {α}_{B1} ) {α}_{A1} + conj ( {α}_{B2} ) {α}_{A2} & {\vert {α}_{B1} \vert}^{2} + {\vert {α}_{B2} \vert}^{2}\end{matrix} ]\end{matrix} \qquad ( 5 )$$

The delays implemented in delay blocks 50,52 are to be selected to provide enough separation between the scrambling code and the delayed version of the same scrambling code, subject to the constraint that the processing delay is tolerable. The design of the delays is a matter of tradeoff between the scrambling code auto correlation property and the hardware processing delay.

One simple set of ‘reflector’ values are α_{A1}=1; α_{A2}=1; α_{B1}=1; α_{B2}=−1 or −2. This set of reflectors results in a unit gain in the two paths over a 1.5 chip duration. It can be verified easily that the corresponding two eigen values are identical. The delay may be determined by the scrambling code auto-correlation property. Using 3GPP/UMTS scrambling code a delay=4.5 chips is a good choice in experience but other values can be used.

Note that the traditional MIMO baseband signals that would be transmitted, respectively, from antenna A 70 and B 72 (in FIG. 4) in the absence of functional blocks 47,49 are

$$\begin{matrix}{S}_{A} ( t ) = {\sum }_{k} {s}_{A} ( k ) {\sum }_{l = 0}^{L - 1} c ( l ) h ( t - lT - ( k - 1 ) LT ) pn ( l + ( k - 1 ) L ) & ( 6 ) \\ {S}_{B} ( t ) = {\sum }_{k} {s}_{B} ( k ) {\sum }_{l = 0}^{L - 1} c ( l ) h ( t - lT - ( k - 1 ) LT ) pn ( l + ( k - 1 ) L ) & ( 7 )\end{matrix}$$

where s_{A}(k) and s_{B}(k) are mapped symbols, c(1) is the lth chip wave-form of the OVSF (Orthogonal Variable Spreading Factor) code, h(t) is the RRC filter with rollover 0.2, L is the length of the OVSF code and pn(t) is the corresponding downlink scrambling code. By comparison, the waveforms being transmitted from antenna A 70 and antenna B 72 for the new systems are for the example delay value of 4.5 T, respectively, expressed as
X_{A}(t)=α_{A1}S_{A}(t)+α_{A2}S_{A}(t-4.5 T) (8)
X_{B}(t)=α_{B1}S_{B}(t)+α_{B2}S_{B}(t-4.5 T) (9)

More generally, delays D1 and D2 may be applied instead of the equal delays 4.5 T.

It is noted that the other channels such as PICH (pilot channel), SCH (synchronous channel), DDCH (dedicated data channel) etc. have been omitted in the diagram and in the equations.

Functional block 47 of FIG. 4A is a very specific way of implementing a spatial reflector function, as provided by an embodiment of the invention. More generally, this function can be implemented as shown in FIG. 4B. Here, the incoming main signal S_{A}(t) is shown being processed along N parallel paths. The first path has no delay. Each of the other paths has a respective delay D₂ 630 through D_{N} 632 which produces a respective delayed signal. Each of the paths is also shown being processed by a respective transformation block. The transformation block for: the first path is indicated at T₁ 634. The transformation block for the second and Nth paths is shown as blocks T₂ 636 and T_{N} 638. This transformation is any path specific processing of the signal which is to be implemented. For example, one path might perform a complex conjugation operation. The paths might include delay specific filtering functions. In the most basic embodiment, the signals pass through the transformations 634,636 . . . 638 unchanged. Each of the paths is then multiplied by a respective virtual spatial reflector α_{A1} 640, α_{A2} 642 through α_{AN} 644. The paths are then combined in adder 646. Each of the delays is different and subject to the same constraints as the single delay embodiment of FIG. 4A. In the most simple implementation, there are only two paths one of which has the delay.

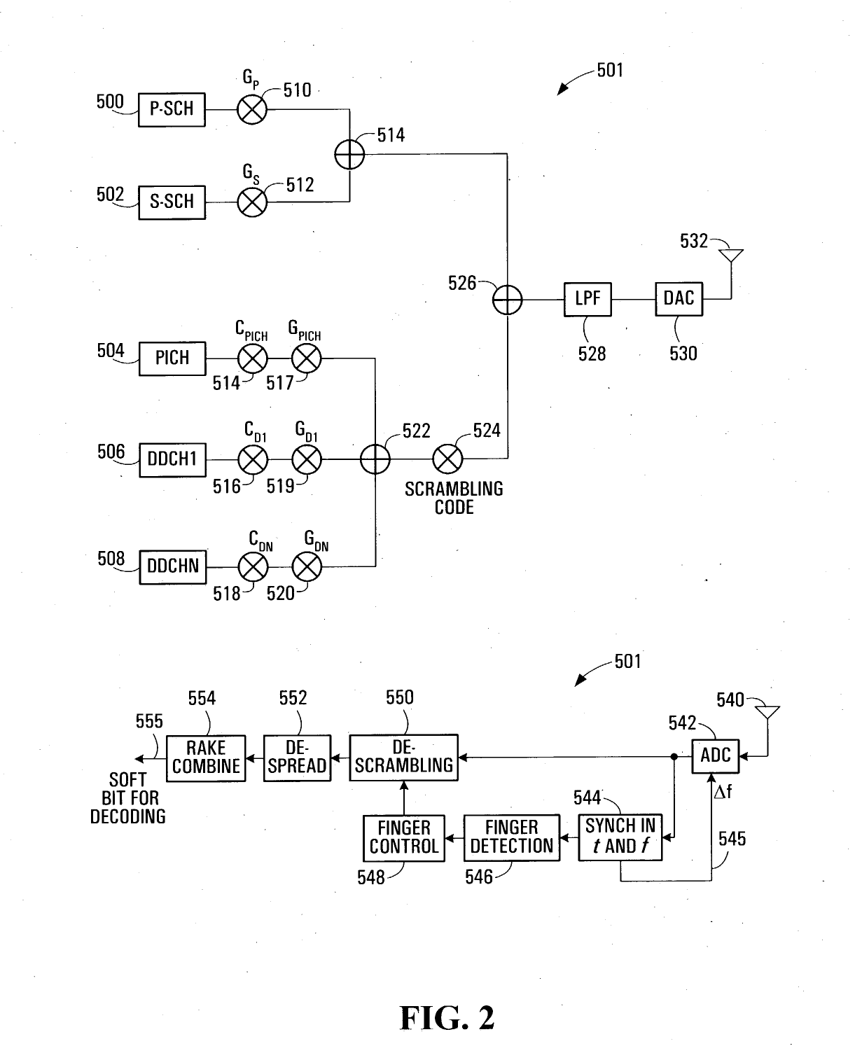

FIG. 4C is a block diagram of how the embodiment of FIG. 4A, using the generic functionality of FIG. 4B can be applied to the CDMA transmitter of FIG. 2. Here, the functionality in respect of the generic channels is indicated at 601 and only shows them being combined in combiner 614. The functionality for one or more user specific channels which are not to be processed by the spatial reflector function is indicated generally at 603. Again all that is shown here is a summer 608 which combines the various channels after having being spread by their respective spreading code, and the scrambling function 610. All of the channels which are not to be processed by the spatial reflector function are combined as 616. The functionality for all of the channels to be processed by the spatial reflector function is generally indicated at 605. Here, all of the channels to be processed are combined at 600, scrambled with scrambling code at 602, and then processed by the spatial reflector function 604. This function can be any appropriate implementation of the generic figure shown in FIG. 4B. The channels which were processed by the spatial reflector function 604 are combined at 612 with the other channels and the result is lowpass filtered at 620 and digital-to-analog converted at 622 and output through the transmit antenna 624. This functionality would be implemented for each of the transmit antennas.

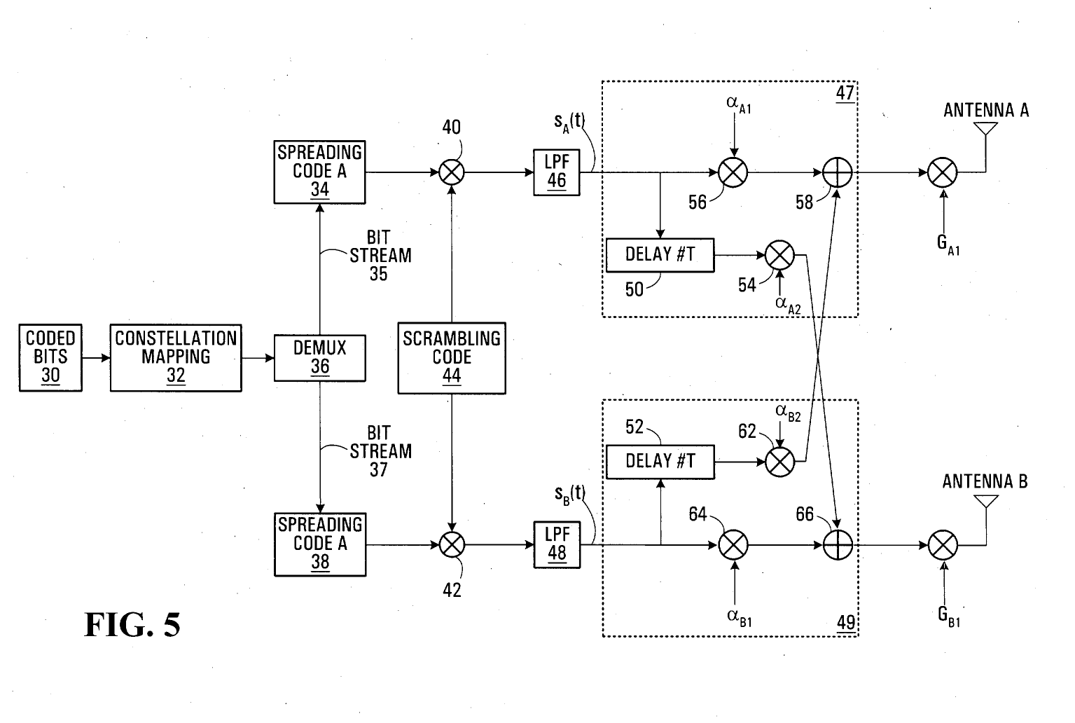

In the example of FIG. 4A, the delayed versions of signals are transmitted by the same antenna as the non-delayed signals. Thus, the signal transmitted by one antenna contains two versions of the same signal. In another embodiment, the delayed signals are transmitted from different antennas than the non-delayed signals. For example, shown in FIG. 5 is a modified version of FIG. 4A adapted to achieve this alternate embodiment. The signal produced by virtual spatial reflector 54 is combined at 66 with the signal produced by virtual spatial reflector 64 and output by antenna B 72. The outputs of the other two virtual spatial reflectors 56,62 are combined and output by the remaining antenna A 70. This changes the transmitted signals to have the following form:
X_{A}(t)=α_{A1}S_{A}(t)+α_{B2}S_{B}(t-4.5T) (10)
X_{B}(t)=α_{B1}S_{B}(t)+α_{A2}S_{A}(t-4.5T) (11)
As in the previous case, more generally two delays D1,D2 may be applied. In either case, one antenna transmits a combination of one of the main signals and one of the delayed signals, and the other antenna transmits a combination of the other of the main signals and the other of the delayed signals.

Thus, a general way to think of the transmitter of FIGS. 4A, or 5 is that the transmitter can be configured to transmit a respective one of N transmit signals from each of the N antennas, the N transmit signals collectively containing a plurality N of main signals and a plurality of delayed main signals, wherein each transmit signal contains a combination of a respective main signal of the plurality of main signals and at least one respective delayed main signal of the N delayed main signals. In this context, “combination” has a broad interpretation. It is meant that there may or may not be a non-identity transformation applied to a given main signal or delayed main signal and there may or may not be non-unity virtual spatial reflectors applied. In this general context, the delayed main signals which are used to generate a given transmit signal may be delayed versions of any of the main signals. The embodiment shown in FIG. 4A had a given antenna transmitting a main signal and a delayed version of the main signal, while the FIG. 5 embodiment had a given antenna transmitting a main signal and a delayed version of another main signal.

In another embodiment, the N transmit signals comprise a Jth transmit signal Transmit_{J} transmitted from antenna J, where J=1, . . . , N, and wherein Transmit_{J} comprises:

$${Transmit}_{J} = {α}_{J} {T}_{J} ( {S}_{J} ) + {\sum }_{i = 1}^{{K}_{J}} {α}_{i J} {T}_{i , J} ( {S}_{i J} ( t - {D}_{i J} ) )$$

S_{J}=is the Jth main signal of the plurality of main signals;
α_{J}=is a virtual spatial reflector applied to the Jth main signal;
T_{J}=is a transformation applied to the Jth main signal;
K_{J} is a number of delayed signals included in the Jth transmit signal as said respective at least one delayed main signal;
α_{iJ}=is a virtual spatial reflector applied to the ith delayed signal included in the Jth transmit signal;
S_{iJ}, i=1, . . . , K_{J} are the signals which are to be delayed and included in the Jth transmit signal where each iJ ε 1, . . . , N as said respective at least one delayed main signal;
Dᵢⱼ=is a delay applied to signal Sᵢⱼ;
T_{iJ}=is a transformation applied to the ith delayed signal included in the Jth transmit signal. Any or all of these transformations may be identity functions (f(x)=x) in which case in a physical implementation they would not exist as a separate function.

As mentioned previously, the transmitter design is easily generalized to more than two transmit antennas. Furthermore, before the physical transmission of-the signals mentioned above, any necessary processing for transmission needs to occur. This is system specific and outside the scope of the invention. Depending on the application, this might involve digital-to-analog conversion, RF up-conversion, channel gain, filtering, and/or other functions.

Furthermore, while a specific transmitter design has been shown, any CDMA transmitter equipped with two or more parallel processing paths each generating main and delayed signals can be employed.

Receiver Design with Virtual Antennas

According to the transmitter diagram (FIG. 4A), the received continuous baseband signal will be:

$$\begin{matrix}y ( t ) = {\sum }_{i = 1}^{I} {β}_{Ai} {x}_{A} ( t - {τ}_{i} ) + {\sum }_{i = 1}^{I} {β}_{Bi} {x}_{B} ( t - {τ}_{i} ) + N ( t ) \\ = {\sum }_{i = 1}^{I} {β}_{Ai} ( {α}_{A1} {S}_{A} ( t - {τ}_{i} ) + {α}_{A2} {S}_{A} ( t - {τ}_{i} - 4.5 T ) ) + \\ {\sum }_{i = 1}^{I} {β}_{Bi} ( {α}_{B1} {S}_{B} ( t - {τ}_{i} ) + {α}_{B2} {S}_{B} ( t - {τ}_{i} - 4.5 T ) )\end{matrix} \qquad ( 12 )$$

where τᵢ is the ith significant multipath with Rayleigh fading coefficients β_{Ai} and β_{Bi}, respectively, I is the number of significant multipaths, and N(t) is a combination of thermal noise, interferences and some ignored multipaths.

Inside the receiver, each multipath component, commonly referred to as a “finger” is detected usually by a pilot correlator. According to the transmitter configuration, statistically the fingers should pop up in pairs with a separation of 4.5 T (or whatever the separation was at the transmitter), in the case of this example, or as pre-defined, i.e. (τᵢ, τᵢ+4.5 T) and both paths associated with the finger pair experience the same Rayleigh fading β_{A1} or β_{Bi}.

For this particular configuration, the finger detection module will identify 2I fingers. Typically, a different pilot will be transmitted by each of the antennas and this pilot is used in searching for multipaths. A separate searching process is conducted for each pilot and a series of multipaths or fingers are identified. In a perfect world, at one receive antenna the fingers detected with the two different pilots will be perfectly aligned. However, due to the actual channel over which the signals are transmitted, they may not be perfectly aligned. When fingers are aligned, they can be treated as pairs. Otherwise, where one significant finger is detected on one pilot but not on the other, it can still be treated as a pair, but with a zero gain on the other pilot. A special case occurs when the signals propagate only along line of sight. Then only two fingers are detected, that is (τ₁, τ₁+4.5 T).

Each finger is treated independently, similar to a RAKE receiver. After de-scrambling and de-spreading, the ith finger pair (τᵢ, τᵢ+4.5 T) processing will output the kth data symbol as
rᵢ₁(k)=β_{Ai}α_{A1}S_{A}(k)+β_{Bi}α_{B1}s_{B}(k)+nᵢ₁(k)
rᵢ₂(k)=β_{Ai}α_{A2}s_{A}(k)+β_{Bi}α_{B2}s_{B}(k)+nᵢ₂(k)
By putting these data pairs into an array, the following matrix equation can be formulated:

$$[ \begin{matrix}{r}_{i1} ( k ) \\ {r}_{i2} ( k ) \\ M \\ {r}_{I1} ( k ) \\ {r}_{I2} ( k )\end{matrix} ] = [ \begin{matrix}{β}_{A1} {α}_{A1} & {β}_{B1} {α}_{B1} \\ {β}_{A1} {α}_{A2} & {β}_{B1} {β}_{B2} \\ M & M \\ {β}_{AI} {α}_{A1} & {β}_{BI} {α}_{B2} \\ {β}_{AI} {α}_{A2} & {β}_{BI} {α}_{B2}\end{matrix} ] [ \begin{matrix}{s}_{A} ( k ) \\ {s}_{B} ( k )\end{matrix} ] + [ \begin{matrix}{n}_{i1} ( k ) \\ {n}_{i2} ( k ) \\ M \\ {n}_{I1} ( k ) \\ {n}_{I2} ( k )\end{matrix} ] \qquad ( 13 )$$

In this configuration, there are two unknowns s_{A}(k) and s_{B}(k) and 2I (≧2) equations. More importantly, the coefficient matrix is always rank-2 whenever β_{A1}≠0 and β_{B1}≠0. So the waveform coding first expands the channel matrix rank and the multipath-rich environment experienced by the signal will further enhance this rank property to favour the MIMO decoder. By using the equation (13), either hard-decision or soft-decision methods can be applied to infer the bits information of s_{A}(k) and s_{B}(k). For example, a simple Least-Mean-Square solution (LMS) can be derived as

$$\begin{matrix}[ \begin{matrix}{s}_{A} ( k ) \\ {s}_{B} ( k )\end{matrix} ] = {{Λ}^{- 1} [ \begin{matrix}{β}_{A1} {α}_{A1} & {β}_{B1} {α}_{B1} \\ {β}_{A1} {α}_{A2} & {β}_{B1} {β}_{B2} \\ M & M \\ {β}_{AI} {α}_{A1} & {β}_{BI} {α}_{B2} \\ {β}_{AI} {α}_{A2} & {β}_{BI} {α}_{B2}\end{matrix} ]}^{T} [ \begin{matrix}{r}_{i1} ( k ) \\ {r}_{i2} ( k ) \\ M \\ {r}_{I1} ( k ) \\ {r}_{I2} ( k )\end{matrix} ] & ( 14 ) \\ Λ = [ \begin{matrix}2 {\sum }_{i = 1}^{I} {\vert {β}_{Ai} \vert}^{2} & \begin{matrix}{\sum }_{i = 1}^{I} {β}_{Ai} {α}_{A1} conj ( {β}_{Bi} {α}_{B1} ) + \\ {β}_{Ai} {α}_{A2} conj ( {β}_{Bi} {α}_{B2} )\end{matrix} \\ \begin{matrix}{\sum }_{i = 1}^{I} conj ( {β}_{Ai} {α}_{A1} ) {β}_{Bi} {α}_{B1} + \\ conj ( {β}_{Ai} {α}_{A2} ) {β}_{Bi} {α}_{B2}\end{matrix} & 2 {\sum }_{i = 1}^{I} {\vert {β}_{Bi} \vert}^{2}\end{matrix} ] & ( 15 )\end{matrix}$$

with
A more sophisticated method such as MLD (Maximum Likelihood Detection) can also be implemented. Equation (13) is very similar to the output of an antenna array and is denoted as a ‘Virtual Antenna Array’.

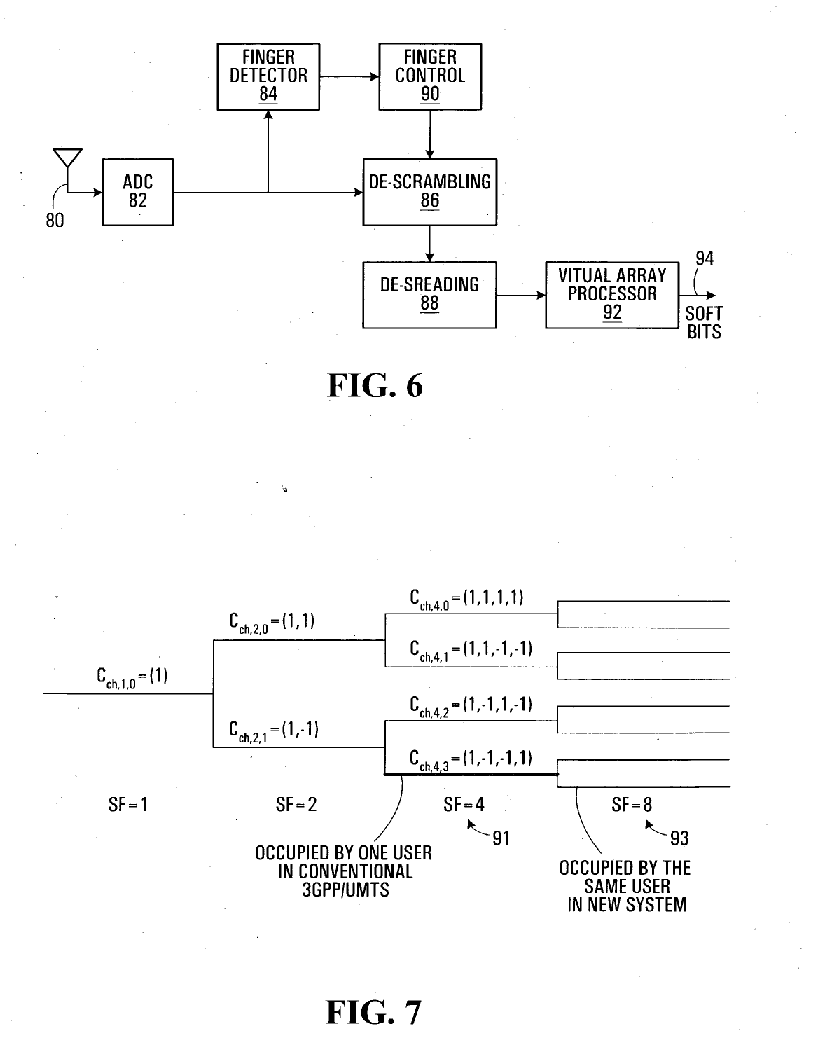

An example of a receiver design is shown in FIG. 6. A single antenna 80 is shown, although the design can be generalized to handle multiple antennas as described further below. It is to be understood a complete receiver would include additional functions not shown in FIG. 6, and these are omitted to simplify the figure. The received signal is digitized in an ADC (Analog-to-Digital Converter) 82. Finger detection occurs in Finger Detector 84 which passes the finger locations thus detected to the Finger Control Function 90. The Finger Control Function 90 controls the de-scrambling operation. 86 and in some cases de-spreading operation 88. Whether or not the Finger Control Function 90 controls both the De-Scrambling Operation 86 and the De-Spreading Operation 88 depends upon a given implementation. The Finger Control Function 90 therefore will also control the overall de-spreading time and data buffer time, but this will vary depending upon whether the implementation is done serially or in parallel. The output signals are fed to a “virtual array processor” 92, i.e. using the above derived array virtual array equations which in turn generates soft bits 94 as the overall output of the circuit of FIG. 4. It is noted that in some designs, de-scrambling and de-spreading operations are done sequentially for the various finger locations by a single hardware implementation. Furthermore, it is noted that for the processing performed in the receiver, once the multiple fingers are identified (twice as many fingers as would be found in the absence of waveform coding) the remainder of the receiver can for the most part be designed according to any otherwise conventional approach.

Advantageously, for the CDMA embodiment, the network capacity is automatically doubled as all the services can be fulfilled by doubling the spreading length compared to the traditional system configuration. Longer spreading not only doubles the code space, but also relaxes the interference level in the whole system. Capacity for a 2×1 system can be written as

$$C = {log}_{2} det ( ( \begin{matrix}1 & 0 \\ 0 & 1\end{matrix} ) + \frac{E \{ s \}}{2} Λ ) bps \text{/} Hz \qquad ( 16 )$$

Where Λ is defined by equation (15).

The downlink signals of each sector/cell are scrambled using the same scrambling code. The same scrambling code with different offsets can be regarded as different orthogonal scrambling codes. Therefore, different fingers can be regarded as different signals carried by different orthogonal scrambling codes (this is similar to OFDM where different tones are used for parallel transmission). Conventional CDMA uses the environment to form a diversity path for different scrambling code offsets. This embodiment actively creates different paths inside the transmitter. Similar to MIMO, those different paths can be either used as diversity paths to increase the receiver SNR as a RAKE receiver does, or used as virtual antenna to gain spectrum efficiency. From equation (15) it can be seen that Λ is a compromise between the cross correlation noise and the eigen mode.

In fact, only half of the fingers are employed to build up a virtual rank-2 channel matrix so that the blasted data stream can be recovered. The limiting factor is still the reception of the cross correlation noise when increasing the number of parallel transmissions. However, there will always be a gain when the network is code space limited. In that situation, the code space is automatically doubled by parallel transmission.

For instance, if a service needs a spreading factor of 4 in the conventional CDMA system the CDMA embodiment only needs to use a spreading factor of 8, which releases half of the OVSF code branch and relaxes the overall interference level to other users.

An example of this is shown in FIG. 7. Channels with a spreading factor 4 are indicated at 91. A single user typically occupies one such channel in conventional 3GPP/UMTS. Spreading factor 8 channels are indicated at 93. Each spreading factor 8 channel takes up half-the code space of spreading factor 4 channel. One user with the CDMA embodiment only needs one spreading factor 8 channel.

OFDM Embodiment

Similar to the CDMA embodiment described above, the OFDM channel can be intercepted before hand to guarantee a suitable channel for MIMO operation. However the interception criteria are different.

An embodiment of the invention provides an OFDM system that will first force the propagation channel to effectively behave like a multipath channel even if it is not. The provision of the pre-designed multipath channel will allow the employment of terminals that have only one receiver antenna provided the MIMO channel matrix embedded in the transmitted signal in frequency domain is full rank. This property of the channel matrix will be further enhanced by the real environment which may also be a multipath-rich environment.

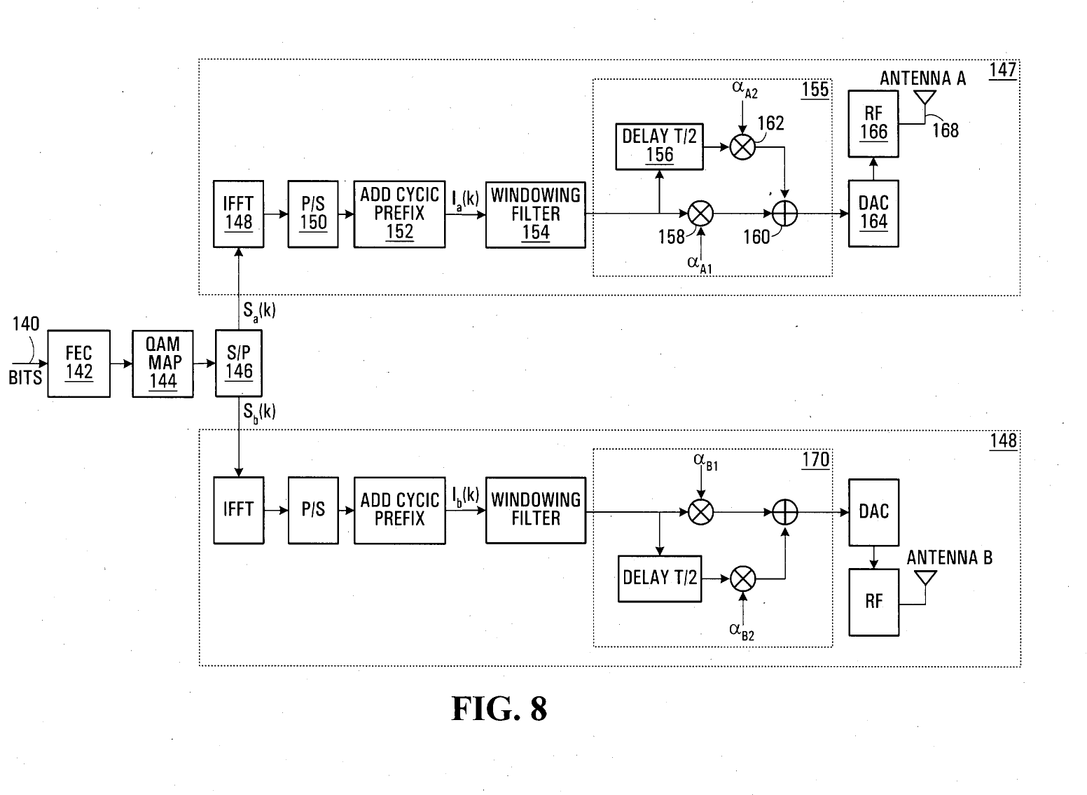

A first example of an OFDM transmitter provided by an embodiment of the invention is illustrated in FIG. 8. Input bits 140 are processed by FEC (Forward Error Correction) coding block 142. This is followed by QAM quadrature amplitude modulation) mapping 144. Other symbol mappings may alternatively be employed. This is followed by a serial-to-parallel conversion function 146 which converts the symbol stream into a parallel stream, and divides the parallel stream into two parallel streams Sₐ(k) and S_{b}(k). The first stream Sₐ(k) is processed by path 147 and the second stream S_{b}(k) is processed by path 148.

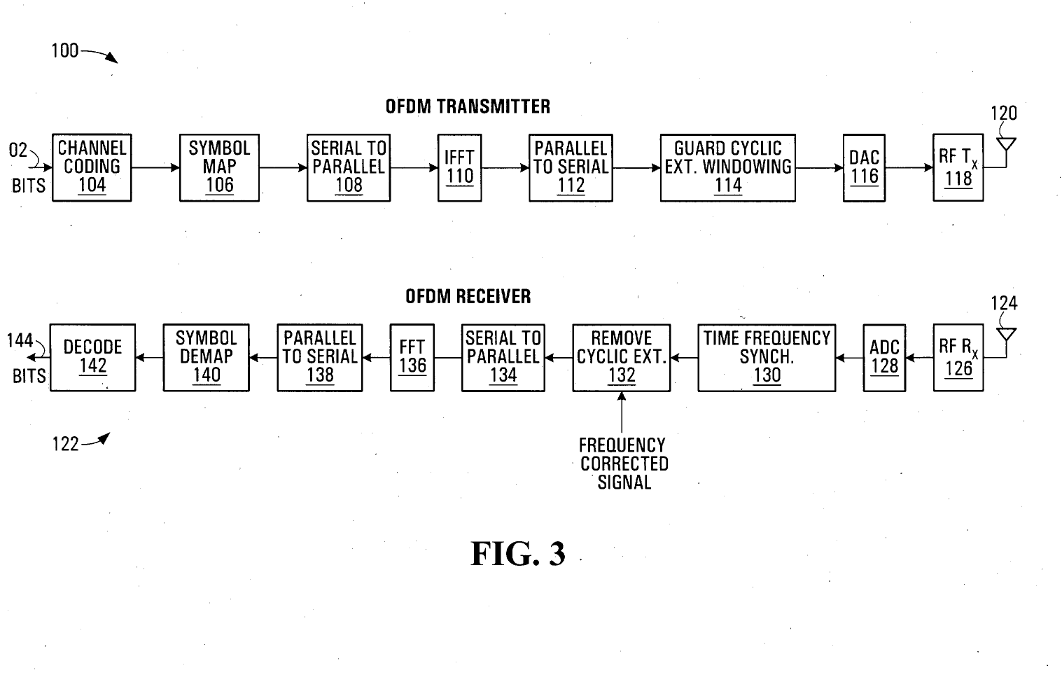

Path 147 begins with an IFFT function 148 followed by a parallel-to-serial function 150. Block 152 adds the conventional cyclic prefix 152 to produce a signal Iₐ(k). Windowing is performed by the windowing filter 154. In this diagram, the windowing filter 154 can be any shaping filter satisfying any provided out-of-band emission specifications. The commonly used window functions are raised cosine, Hamming or Hanning windows. The output of the windowing filter 154 is then processed by block 155, which is very similar to block 47 of FIG. 3 for the CDMA embodiment.

In functional block 155, the output of the windowing filter 154 is multiplied by a virtual spatial reflector α_{A1} 158. The windowing filter output is also delayed in delay block 156 having a delay of T/2 in the illustrated embodiment where T is the OFDM symbol duration. Other delay values may be used. The delayed signal is then multiplied by a second virtual spatial reflector, α_{A2} 162. The outputs of the two virtual reflectors 158,162 are combined in adder 160. The output is then converted to analog form with DAC 164 that is connected to RF transmitter 166 which outputs the signal,to transmit through the antenna 168.

The processing in the second path 148 is the same as in the first path except that in processing block 170 different virtual spatial reflectors α_{B1} and α_{B2} are employed.

One simple set of reflectors that can be used with the embodiment of FIG. 8 is α_{A1}=1, α_{A2}=1, α_{B1}=1, α_{B2}=−2.

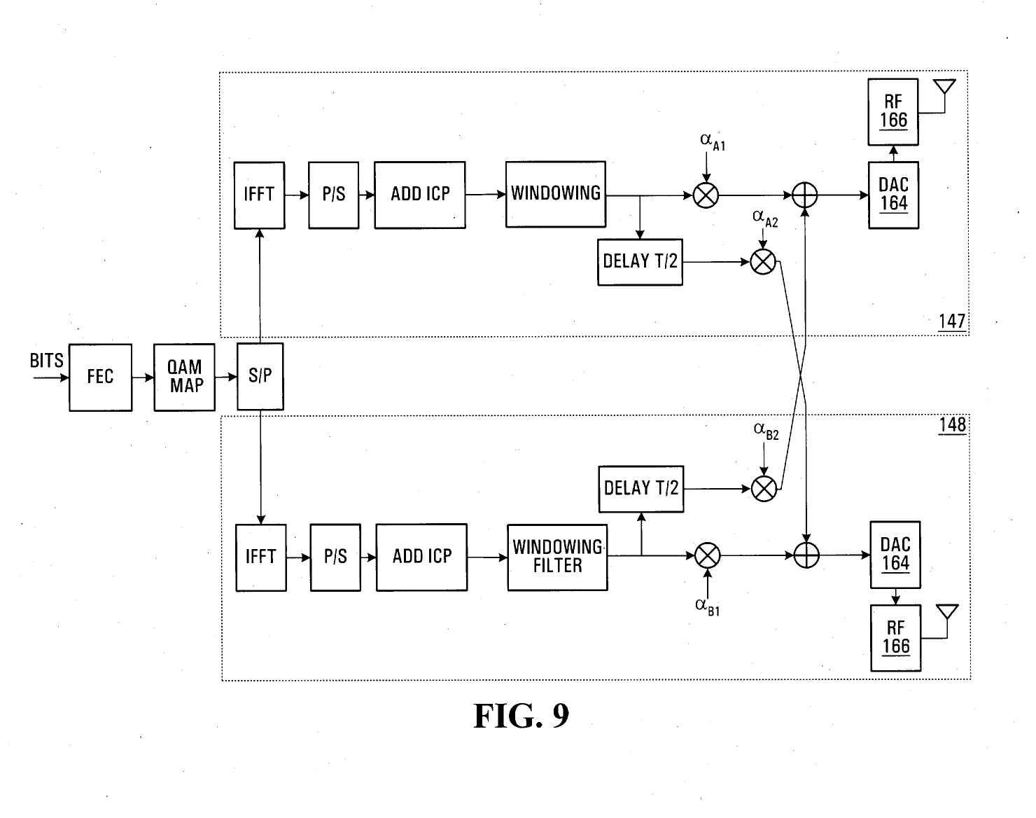

In another embodiment, the delayed versions can also be transmitted from different transmitters as illustrated in FIG. 9. FIG. 9 is the same as FIG. 8 with the exception of the fact that each output signal is generated from a combination of the output of one spatial reflector in the first path 147 and the output of one spatial reflect in the second path 148 similar to the CDMA embodiment of FIG. 5 described previously.

OFDM Multi-Path Propagation

In this section and the forthcoming sections, analysis is presented for the embodiment of FIG. 8 only. The analysis for the embodiment of FIG. 9 is similar. Furthermore, for embodiments with more than two transmitters, the analysis is the same with a little bit more effort on optimizing the delays and interception parameters.

In conventional systems, the shaped OFDM symbol is transmitted after DAC and PA (power amplification) and is propagated to the receiver via the environmental multipath channels

$$\begin{matrix}{ch}_{A} ( t ) = {\sum }_{k = 1}^{{K}_{A}} {α}_{A} ( k ) rect ( t - {τ}_{A}^{k} ) & ( 17 ) \\ {ch}_{B} ( t ) = {\sum }_{k = 1}^{{K}_{B}} {α}_{B} ( k ) rect ( t - {τ}_{B}^{k} ) & ( 18 )\end{matrix}$$

where rect(t) is the rectangular shaping function which is defined as rect(t)=1 when t is between -T/2 and T/2 and 0 elsewhere.

Note that the impulse responses of both channels are time limited in theory and therefore sampling the channels at the Nyquist rate can only provide partial channel information or the sampled channel spectrum will be affected by aliasing. In other words, over sampling these channels will always provide more information on the multipath channels compared to Nyquist rate sampling. To illustrate the multipath channel over sampling concept using the example transmitter configuration (with α_{A1}=1, α_{A2}=1, α_{B1}=1, α_{B2}=−2) suppose the channels are LOS (line of sight) with a channel gain equal to one, i.e. the ideal non-scattering environment. This is a special case in which the conventional MIMO blast technique does not work properly. In this case,
ch_{A}(t)=rect(t)+rect(t-T/2) (19)
is the channel output at antenna A and
ch_{B}(t)=rect(t)−2rect(t-T/2) (20)
is the channel output at antenna B.

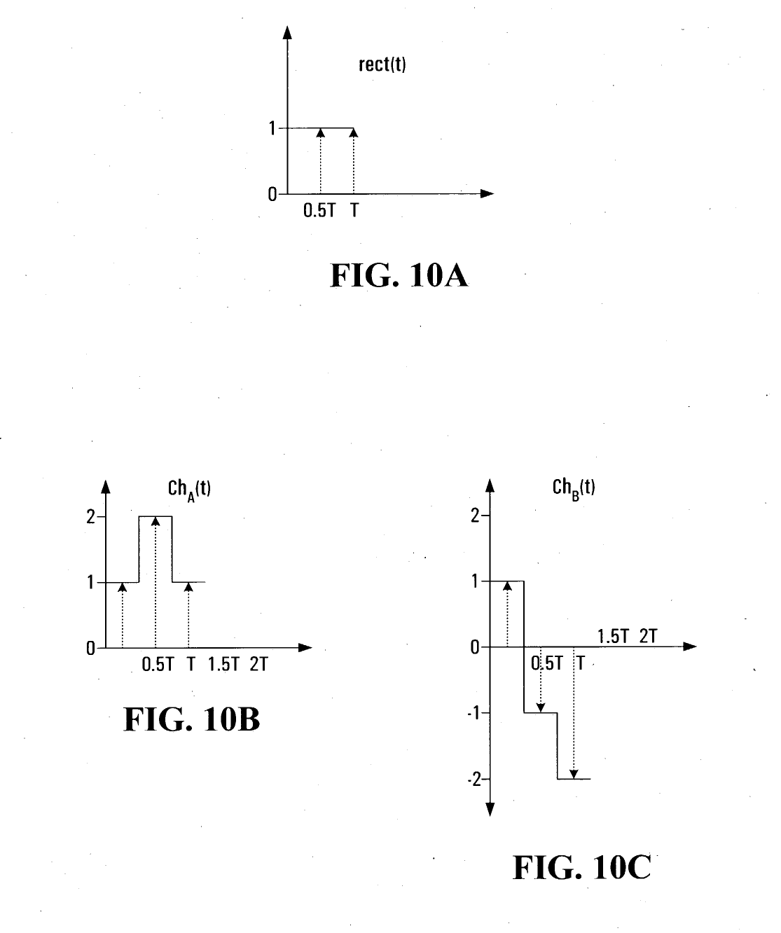

The conventional channel is shown in FIG. 10A. The channel represented by equation 19 is shown in FIG. 10B, and the channel represented by equation 20 is shown in FIG. 10C. The dotted arrows indicate the sampling instants, which are T/2 apart. With this simple waveform coding, the odd and even samples of channels are quite different for the channels shown in FIGS. 10B and 10C compared to conventional OFDM that goes through the rectangular channel of FIG. 10A. For the channel of FIG. 10B, for instance, the odd and even channel samples are Ch_{Ao}=[1 1 0 . . . 0] and Ch_{Ae}=[2 0 0 . . . 0] while for the channel of FIG. 10C Ch_{Bo}=[1 −2 0 . . . 0] and Ch_{Ae}=[−1 0 0 . . . 0]. This odd and even channel difference will cause their frequency domain impulse responses to vary and therefore a full rank channel matrix with high probability is generated in the frequency domain. In fact, for the above simple case, the channel gains for the kth tone can be calculated respectively as F_{Ao}(k)=1+exp(−j2π/1024)2k, F_{Bo}(k)=1−2exp(−j2π/1024)2k, F_{Ae}(k)=2 and F_{Be}(k)=−1. They form the kth tone channel matrix:

$$[ \begin{matrix}{F}_{Ao} ( k ) & {F}_{Bo} ( k ) \\ 2 & - 1\end{matrix} ]$$

which always has a full rank.

Note that for this example, the powers from two different antennas are balanced within a 1.5T time interval, and the signal spectrum stays the same as the conventional OFDM system.

It is noted that in the transmitters of FIGS. 8 and 9, each path of the transmitters are similar to conventional transmitters except for splitting the QAM mapped signal between the-two paths, and the waveform coding performed by functional blocks 155,170. Thus, where a particular implementation for the remainder of the transmitter is shown, more generally an embodiment of the invention provides any transmitter equipped to perform the described waveform coding for two or more transmit signals.

OFDM Receiver

In general, the blasted signals {Iₐ(k)} and {I_{b}(k)} (refer to FIG. 8) will propagate along the multipath channels ch_{A}(t) and ch_{B}(t) respectively that have been defined in equations (17) and (18). With the new waveform coding, they will propagate with the intercepted multipath channels which can be expressed respectively as

$$\begin{matrix}{ch}_{AI} ( t ) = {\sum }_{k = 1}^{{K}_{A}} {α}_{A} ( k ) [ {α}_{A1} rect ( t - {τ}_{A}^{k} ) + {α}_{A2} rect ( t - \frac{T}{2} - {τ}_{A}^{k} ) ] & ( 21 ) \\ {ch}_{BI} ( t ) = {\sum }_{k = 1}^{{K}_{B}} {α}_{B} ( k ) [ {α}_{B1} rect ( t - {τ}_{B}^{k} ) + {α}_{B2} rect ( t - \frac{T}{2} - {τ}_{B}^{k} ) ] & ( 22 )\end{matrix}$$

The received baseband signal (for one antenna) can be modeled as

$$y ( t ) = {\sum }_{k} {I}_{a} ( k ) {ch}_{AI} ( t - kT ) + {\sum }_{k} {I}_{b} ( k ) {ch}_{BI} ( t - kT ) + n ( t ) \qquad ( 23 )$$

Discretizing y(t) will simultaneously sample the multipath channels. Suppose y(t) is sampled at two times the Nyquist rate, i.e. y(t) is discretized as

$$\begin{matrix}\{ y ( m \frac{T}{2} ) = {\sum }_{k} {I}_{a} ( k ) {ch}_{AI} ( m \frac{T}{2} - kT ) + & ( 24 ) \\ {\sum }_{k} {I}_{b} ( k ) {ch}_{BI} ( m \frac{T}{2} - kT ) + n ( m \frac{T}{2} ) \vert m = 0 , 1 , 2 , … \} & \end{matrix}$$

These samples can be classified by odd or even indexed samples, i.e.

$$\begin{matrix}\{ {y}_{o} ( l ) = {\sum }_{k} {I}_{a} ( k ) {ch}_{AI} ( lT + \frac{T}{2} - kT ) + {\sum }_{k} {I}_{b} ( k ) {ch}_{BI} ( lT + \frac{T}{2} - kT ) + & ( 25 ) \\ n ( lT + \frac{T}{2} ) \vert l = 2 m + 1 , m = 0 , 1 , 2 , … \} & \\ and & \\ \{ {y}_{e} ( p ) = {\sum }_{k} {I}_{a} ( k ) {ch}_{AI} ( pT - kT ) + & ( 26 ) \\ {\sum }_{k} {I}_{b} ( k ) {ch}_{BI} ( pT - kT ) + n ( pT ) \vert p = 2 m , m = 0 , 1 , 2 , … \} & \end{matrix}$$

The odd samples can be regarded as the acquisition of a signal that equals the transmitted data symbols transmitted on the odd multipath channel whilst the even samples can be regarded as the acquisition of a signal that equals the same transmitted data symbols transmitted on the even multipath channel. Note that for conventional OFDM, these odd and even samples are the same when in a LOS environment as the odd and even paths are the same.

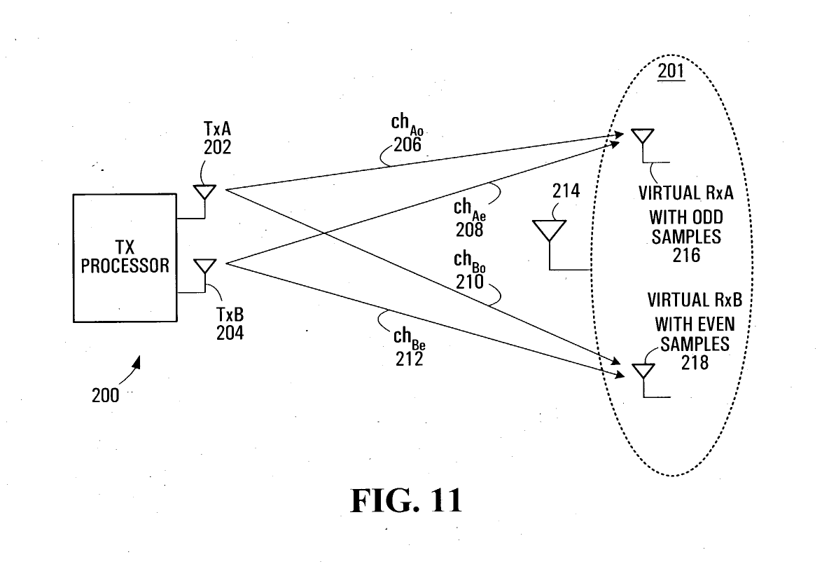

As has been shown for the new waveform coding, odd multipath channels
{ch_{Ao}(m)=ch_{A}(mT+0.5T)|m=0, 1, 2 . . . }
and
{ch_{Bo}(m)=ch_{B}(mT+0.5T)|m=0, 1, 2 . . . }
are always quite different from even channels
{ch_{Ae}(m)=ch_{A}(mT)|m=0, 1, 2, . . . }
and
{ch_{Be}(m)=ch_{B}(mT)|m=0, 1, 2, . . . }.
Their corresponding frequency contents are forced to change at each delay instant and are also modulated with the natural Rayleigh fading coefficients. Odd and even samples of y(t) can be regarded as coming from two different imaginary receiver antennae RxA and RxB which take samples at T-space. This is illustrated diagrammatically in FIG. 11, which shows a virtual spatial antenna configuration. This shows a transmitter generally indicated at 200 having two transmit antennae TxA 202 and TxB 204. Also shown is a receiver generally indicated at 201 having a single receive antenna 214. By performing the above discussed division between even and odd samples taken at the receiver 201, effectively there is a first virtual RxA 216 which receives odd samples and a second virtual RxB 218 which receives even samples. Then, there are the four channels shown, namely ch_{Ao} 206 between TxA and RxA, ch_{Ae} 208 between TxA and RxB, ch_{Be} 212 between TxB and RxB, and ch_{Bo} 210 between TxB and RxA. This results in the same effective number of channels as in the conventional MIMO scenario requiring two receive antennas.

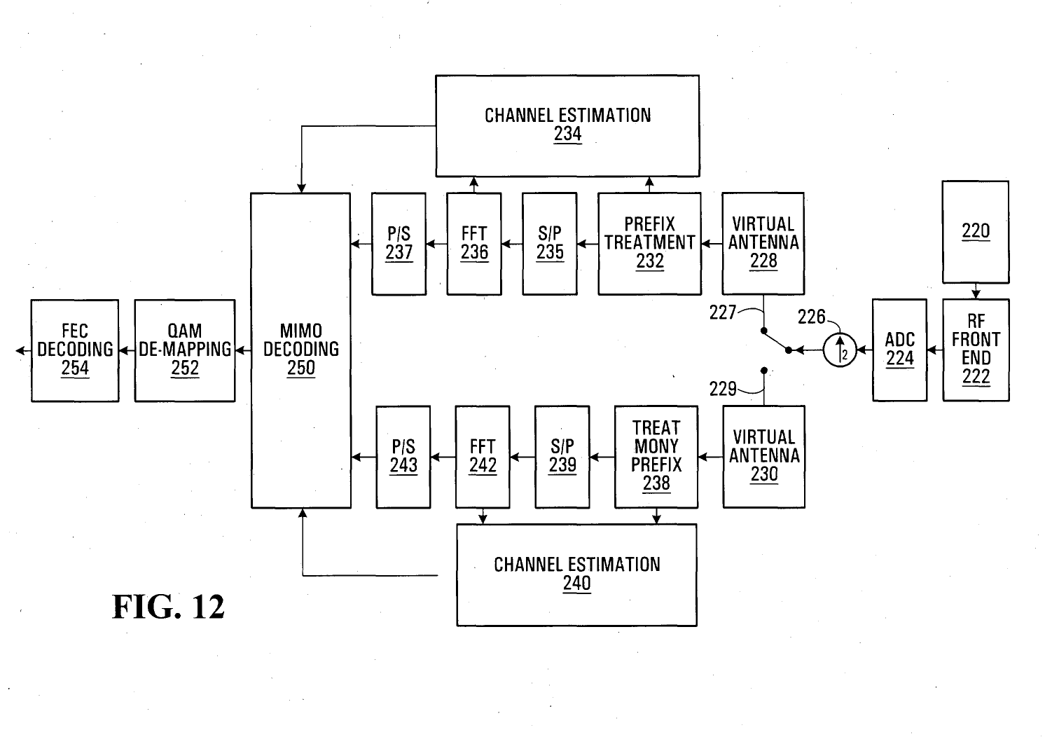

A block diagram of an example OFDM receiver is provided in FIG. 12. Reception begins at the single receive antenna 220 through the RF front end 222. Analog to digital conversion occurs with ADC 224. Next sample collector 226 extracts the odd samples produced by the ADC 224 to produce an odd sample stream 227 and extracts the even samples produced by the ADC 224 to create even sample stream 229. Virtual antennae 228,230 are shown which effectively receive the odd sample stream 227 and the even sample stream 229 respectively but no such physical antennae exist, rather only the single receive antenna 220 is provided. Processing of the odd sample stream 227 and the even sample stream 229 then progresses basically in the conventional manner described previously with reference to FIG. 3. The prefix is extracted at 232. Serial-to-parallel conversion takes place at 235. FFT occurs at 236 followed by parallel-to-serial conversion 237 which produces a pre-combined output. The outputs of functions 232,236 are used by channel estimation function 234 to develop a channel estimate for the odd channel. The output of the parallel-to-serial converter 237 and output of the channel estimator function 234 are input to a MIMO decoding function 250. Similarly, for the even sample stream 229, the cyclic extension is removed at 238 followed by serial-to-parallel conversion 239, FFT 242 and parallel-to-serial conversion 243 which is another pre-combined output. Channel estimation takes place as indicated at 240. The output of the parallel-to-serial converter 243 and output of the channel estimator function 240 are input to a MIMO decoding function 250.

The MIMO decoding function 250 performs MIMO decoding/combination of the pre-combined outputs using any technique, conventional or otherwise. The output of MIMO decoding 250 is processed by the QAM de-mapping function 252 and this is followed by FEC decoding 254. It is important to realize that after the splitting of the input samples into even and odd streams 227,229, the remainder of the receiver can be built identically to any two antenna MIMO receiver. For example, in one embodiment, the MIMO decoding might be MRC (maximum ratio combining) combining, in which the outputs of the FFTs are simply weighted by the channel estimates and combined. Other decoding approaches might alternatively be employed, and this may change the manner in which the even and odd sample streams are processed.

Theoretically, the correlation between the odd samples channel and even samples channel depends on the bandwidth of the multipath channel (not to be confused with the signal bandwidth). Their mutual dependency reduces as the Multipath-Channel-Bandwidth increases. The odd samples channel and even samples channel may be partially correlated with each other in time. However, they always have quite different frequency responses, which enables the virtual antenna setup in the receiving end though only one physical antenna exists. This phenomenon is true for every wireless system and is well suited for an OFDM system-as the shaping function of OFDM system is a rectangular pulse.

It is possible to return to the frequency domain by performing a FFT on both the odd samples channel and the even samples channel. The receiver model for the nth tone can be expressed as

$$[ \begin{matrix}{Y}_{o} ( n ) \\ {Y}_{e} ( n )\end{matrix} ] = [ \begin{matrix}{H}_{ao} ( n ) & {H}_{bo} ( n ) \\ {H}_{ae} ( n ) & {H}_{ae} ( n )\end{matrix} ] [ \begin{matrix}{s}_{a} ( n ) \\ {s}_{b} ( n )\end{matrix} ] + [ \begin{matrix}{N}_{e} ( n ) \\ {N}_{o} ( n )\end{matrix} ] \qquad ( 27 )$$

where, Hₐₑ(n), H_{be}(n), Hₐₒ(n) and H_{bo}(n) are the frequency domain channel responses for the nth tone. Therefore MIMO decoding techniques can be applied whenever the channel matrix is full rank. The capacity of this embodiment will solely depend on the eigen condition of the channel matrix.
OFDM Transmitter Parameters Optimization

For the above example 2×1 FIG. 8 embodiment, α_{A1}=1; α_{A2}=1; α_{B1}=1; α_{B2}=−2 were the values used. These four parameters can be optimized in terms of capacity or frequency domain channel conditions. The following are several rules/constraints which may be employed alone or in any combination to optimize these parameters.
a) balanced energy: |α_{A1}|²+|α_{A2}|²+|α_{A1}+α_{A2}|²=|α_{B1}|²=|α_{B2}|²+|α_{B1}+α_{B2}|²;
b) there is no large notch in frequency domain;
c) the capacity is maximized; and
d) meet the spectrum mask i.e. the signal stays within a required band.

Odd and even channel taps will make frequency domain channel response vary significantly. In fact, the odd and even channels absorb different multipaths and are therefore helpful when a set of multipaths form a destructive signal or when multipaths are formed by a wide scattering environment. To precisely describe this statement, one can classify the random delays by the following index classification

$$\begin{matrix}{I}_{A1} ( n ) = \{ k \vert ( n - 1 ) T < {τ}_{A}^{k} \leq nT \} & ( 28 ) \\ {I}_{A2} ( n ) = \{ k \vert nT - \frac{T}{2} < {τ}_{A}^{k} \leq nT + \frac{T}{2} \} & ( 29 ) \\ {I}_{A3} ( n ) = \{ k \vert nT < {τ}_{A}^{k} \leq ( n + 1 ) T \} & ( 30 )\end{matrix}$$

Then the channels sampled at even (2nT/2) and odd ((2n+1)T/2) intervals can be explicitly expressed as:

$$\begin{matrix}{ch}_{A}^{e} ( n ) = {ch}_{A} ( 2 nT / 2 ) = {α}_{A2} {\sum }_{k ∈ {I}_{A1}} {α}_{A} ( k ) + {α}_{A1} {\sum }_{k ∈ {I}_{A2}} {α}_{A} ( k ) & ( 31 ) \\ {ch}_{A}^{o} ( n ) = {ch}_{A} ( 2 nT / 2 + T / 2 ) = {α}_{A1} {\sum }_{k ∈ {I}_{A3}} {α}_{A} ( k ) + {α}_{A2} {\sum }_{k ∈ {I}_{A2}} {α}_{A} ( k ) & ( 32 )\end{matrix}$$

Similarly for channel B:

$$\begin{matrix}{ch}_{B}^{e} ( n ) = {ch}_{B} ( 2 nT / 2 ) = {α}_{B2} {\sum }_{k ∈ {I}_{B1}} {α}_{B} ( k ) + {α}_{B1} {\sum }_{k ∈ {I}_{B2}} {α}_{B} ( k ) & ( 33 ) \\ {ch}_{B}^{o} ( n ) = {ch}_{B} ( 2 nT / 2 + T / 2 ) = {α}_{B1} {\sum }_{k ∈ {I}_{B3}} {α}_{B} ( k ) + {α}_{B2} {\sum }_{k ∈ {I}_{B2}} {α}_{B} ( k ) & ( 34 )\end{matrix}$$

Hence it can be seen that that the index sets I_{A1}(n), I_{A2}(n), I_{A3}(n) (also I_{B1}(n), I_{B2}(n), I_{B3}(n)) are functions of the random delays which are environmentally determined factors. More importantly, I_{A1}(n) and I_{A3}(n) are disjoint. Along with the channel interception parameters and Rayleigh fading, the even and odd samples of the channel do have a significant variation that will provide frequency diversity and build up the channel rank of a MIMO decoder with only one receiver antenna.

Particularly, when I_{A2}(n) and I_{B2}(n) are empty, the corresponding odd and even channel responses are independent.

It is noted that CDMA pioneers also considered the selection of multipaths to form each individual finger by controlling the chip rate [J. Shapira and C. E. Wheatley, Channel based optimum bandwidth for spread spectrum land cellular radio, Qualcomm, 1992.]. In practice, it is very difficult to control the amount of ambiguity of a designated finger to have a large amount of mutual information. Unfortunately, the theoretical results show that CDMA systems tends to diminish the mutual information when all the multipaths are resolvable. This occurs when the chip rate is large enough. OFDM seems not to have that issue as it always considers the multipaths together. This might be another advantage of an OFDM system over a CDMA system with a RAKE receiver.

Conventional MIMO passively exploits the spatial channels and therefore requires the environment must be rich scattering and a non-keyhole environment. Keyhole environments are elaborated upon below. When the real environment is LOS (this situation comprises 15% of the cases in urban areas) or keyhole, MIMO does not work properly. The embodiment is different in the sense that it intercepts the channels first to make the spatial channel a type having wide and rich scattering even if it would otherwise not.

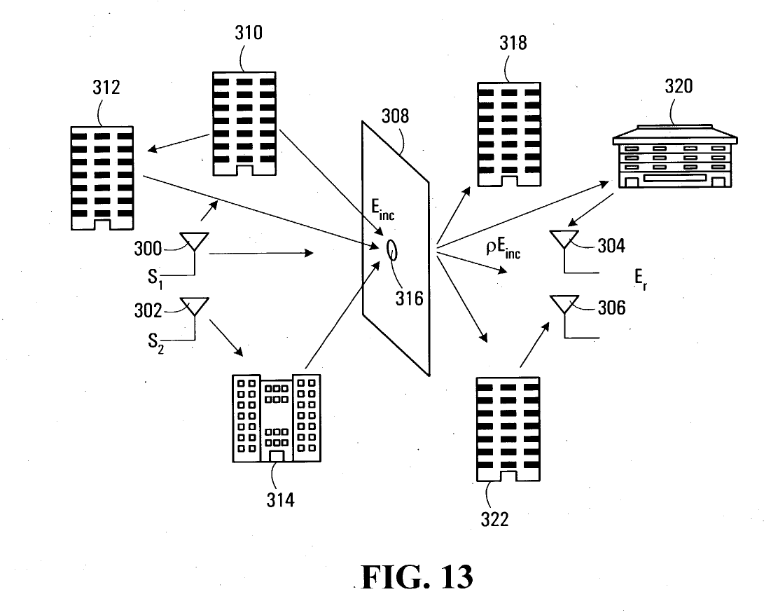

Advantageously, embodiments of the invention do not suffer a loss in Keyhole Environments. A keyhole environment is one that will force waves propagating along multiple paths to recombine and then continue propagating with the appearance of a single wave. In FIG. 13 there are two transmitting antennae 300,302 and two receiving antennae 304,306. Transmission waves start to propagate from the two transmitting antennae 300,302. When the signals hit surrounding obstacles 310,312,314, they get scattered and multiple waves are generated by reflection or diffraction. If a large shielding wall 308 is considered between the transmitters and receivers the keyhole phenomenon acts as a small hole 316 in the wall that transmission of the multiple paths is directed towards and the signals can pass through.

The combined electric field incident on the keyhole can be expressed as
E_{inc}=α₁s₁+α₂s₂ (43)
Where α₁ and α₂ are caused by the multiple scattering objects 310,312,314 surrounding the transmitters 300,302. After passing through the keyhole, the electric intensity becomes ρE_{inc} due to the scaling effect of the keyhole ρ. So the received electric field vector of the two receiver antennae can be written as

$${E}_{r} = [ \begin{matrix}{β}_{1} \\ {β}_{2}\end{matrix} ] ρ {E}_{inc} + N = ρ [ \begin{matrix}{β}_{1} \\ {β}_{2}\end{matrix} ] [ \begin{matrix}{α}_{1} & {α}_{2}\end{matrix} ] [ \begin{matrix}{s}_{1} \\ {s}_{2}\end{matrix} ] + N \qquad ( 44 )$$

where β₁ and β₂ are caused by the scattering objects 318,320,322 surrounding the receiving antennae.

The Keyhole phenomenon was first noticed by Lucent [Dmitry, Chizhik, G. J. Foschini, M. J. Gans and R. A. Valenzuela, Keyholes, correlations, and capacities of multi-element transmit and receive antennas, IEEE Transactions on Wireless Communications, Vol. 1, No. 2, 2002, pp 361-368.]. In particular roof edge diffraction is perceived as creating a keyhole effect as is the indoor hallway environment. It has been observed by Lucent that the keyhole effect significantly reduces the MIMO BLAST capacity. As a matter of fact, the channel matrix (ref. equation (44)) is always a rank-1 matrix and therefore MIMO blasting capacity collapses to a single transmit and single receive system channel capacity. With the embodiments of the invention, due to the waveform coding transmission technique the keyhole effect will not pose a problem in the statistical sense.

Multiple Receiver Embodiment

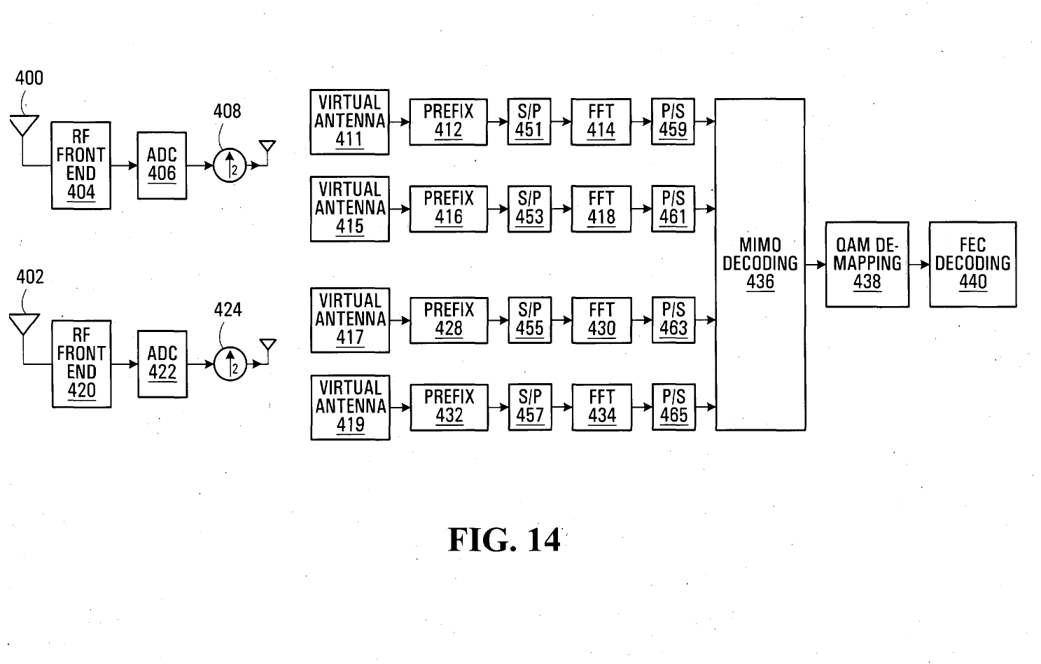

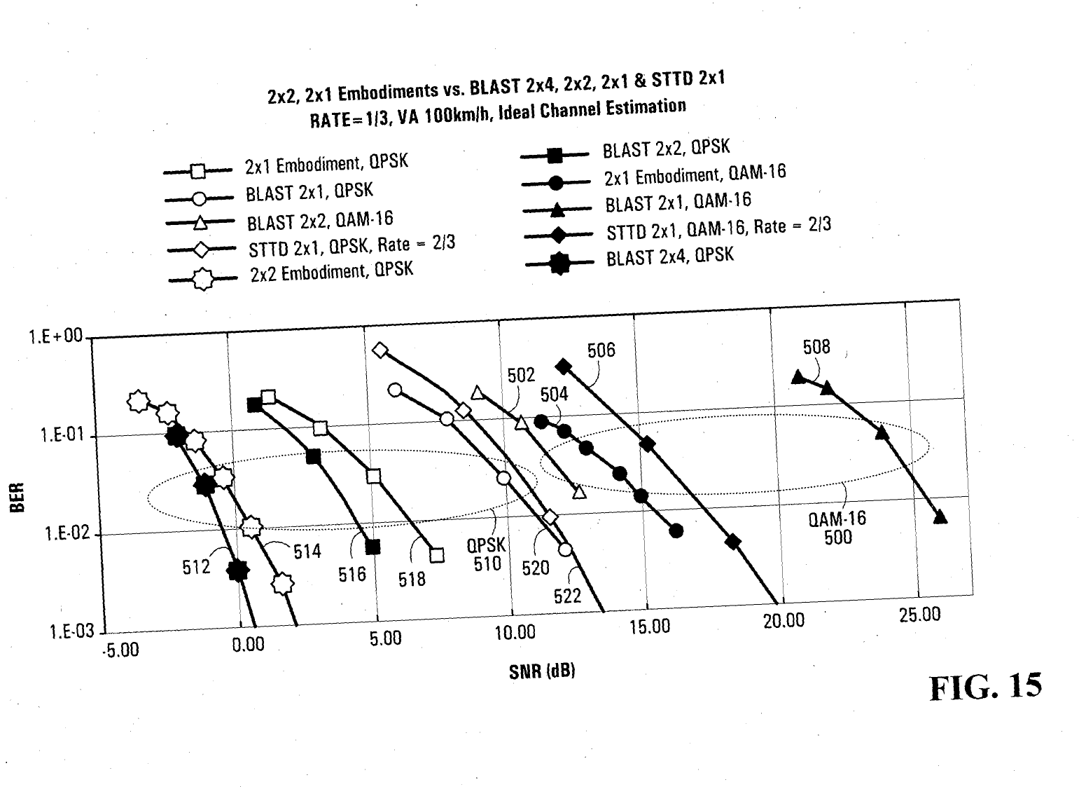

In the previous section, only multiple transmitter and single receiver systems have been discussed. However, more generally, embodiments can be used either in single receiver antenna systems or multiple receiver antennae system. In fact, the technology can be fully exploited in MIMO systems to produce a robust transceiver system while maintaining a low cost. For example, 2×4 MIMO system performance can be achieved with 2×2 MIMO systems with the invented technology built in. FIG. 14 illustrates a 2×2 MIMO receiver diagram provided by an embodiment of the invention that has similar performance to a MIMO 2×4 system.

Two antennae 400,402 are used to receive the incoming signals. A RF receiver 404 accepts the signal from antenna 400 and from there it proceeds to the ADC 406. The stream is split into even and odd paths with sample collector 408 and then framed 410 before undergoing prefix treatment 412,416. The processing done in combining the received signals is somewhat different. The virtual array processing is conducted instead of the RAKE receiver processing. This amounts to a software change in a receiver. The two paths undergo respective serial-to-parallel conversion 451,453, FFT 414,418, parallel-to-serial conversion 459,461 the outputs of which are fed to MIMO decoding function 436. Similarly, the other antenna 402 receives a signal and it proceeds to the RF receiver 420 before the bits continue on to the ADC 422. The bit stream is split at 424. The two bit streams are then processed by prefix treatments functions 428,432, serial-to-parallel converters 455,457, FFT functions 430,434 and parallel-to-serial converters 463,465 the outputs of which are fed to the MIMO decoding function 436. Also shown in the figure are the four virtual antennas 411,415,417,419, but as in previous embodiments these virtual antennas do not exist in the physical sense. The outputs of the four FFT stages 414,418,430,434 are combined in the MIMO processing engine which results in an output being sent to the QAM de-mapping function 438. At this point the bit stream undergoes FEC decoding 440.

It can be seen that a 2×2 MIMO system is equivalent to the 2×4 MIMO system with a significant cost reduction. The FIG. 14 embodiment includes functionality after separating the two received signals into four streams which is basically equivalent to a four antenna system. Any four antenna processing approach can be followed. The figure shows only one example. In general, Mᵣ receive antennas can achieve pMᵣ receive antennas performance with p times over sampling along with the pre-channel interception. P times over sampling would be required in a system implementing the general virtual spatial reflector of FIG. 4B with p paths.

Simulation Setup and Link Performance

Simulations were performed using a well developed OFDM Prototype Simulator. The results were obtained by simultaneously running the prototype 2×2 system configurations and 2×1 system configuration side by side. All the simulation parameters were kept the same except that the implementation of the invention uses only a single receiver antenna output and two times over sampling. The simulation results show that the performance of a 2×1 embodiment (using either. QAM or QPSK) is comparable to that of a MIMO 2×2 system (again using either QAM or QPSK). The 2×1 embodiment is also shown to outperform the conventional 2×1 BLAST with MLD or 2×1 STTD when they are restricted to the same throughput. An additional simulation was run for a 2×2 embodiment and a BLAST 2×4 system. It can be seen that the 2×2 embodiment again has comparable performance to the more elaborate BLAST 2×4 system. In FIG. 14 the two groups of curves have been plotted. The first group represents the simulation on QPSK modulation 510 with the six transmission-reception schemes (i.e. 2×1 embodiment 518, BLAST 2×1 520, BLAST 2×2 516, STTD 2×1 522, 2×2 embodiment 214 and BLAST 2×4 512). The second group 500 represents the simulation applying QAM-16 to four of the same transmission-reception schemes (2×1 embodiment 504, BLAST 2×1 508, BLAST 2×2 502, STTD 2×1 506. Note that BLAST 2×1 is new and has been simulated with an advanced MLD decoder that best suits the system in order to provide a fair comparison of the systems.

1. A transmitter comprising:
N transmit antennas, where N>=2;
wherein the transmitter is adapted to transmit a respective one of N transmit signals from each of the N antennas, the N transmit signals collectively containing a plurality N of main signals and a plurality of delayed main signals each delayed main signal being a delayed version of one of the main signals, wherein each transmit signal comprises a combination of a respective main signal of the plurality of main signals and at least one respective delayed main signal of the N delayed main signals.

2. The transmitter of claim 1 wherein the N transmit signals comprise a Jth transmit signal Transmit_{J} from antenna J=1, . . . , N, and wherein Transmit_{J} comprises:
$${Transmit}_{J} = {α}_{J} {T}_{J} ( {S}_{J} ) + {\sum }_{i = 1}^{{K}_{J}} {α}_{iJ} {T}_{i , J} ( {S}_{iJ} ( t - {D}_{iJ} ) )$$
S_{J}=is the Jth main signal of the plurality of main signals;
α_{J}=is a virtual spatial reflector applied to the Jth main signal;
T_{J}=is a transformation applied to the Jth main signal;
K_{J} is a number of delayed signals included in the Jth transmit signal;
α_{iJ}=is a virtual spatial reflector applied to the ith delayed signal included in the Jth transmit signal;
S_{iJ}, i=1, . . . , K_{J} are the signals which are to be delayed and included in the Jth transmit signal where each iJ ε 1, . . . , N;
D_{iJ}=is a delay applied to signal S_{iJ};
T_{iJ}=is a transformation applied to the ith delayed signal included in the Jth transmit signal.

3. The transmitter of claim 2 wherein each transmit signal comprises a CDMA (Code Division Multiple Access) signal.

4. The transmitter of claim 3 wherein each main signal comprises a respective combined set of at least one code separated channel.

5. The transmitter of claim 4 wherein each transmit signal further comprises at least one additional code separated channel not included in any main signal.

6. A transmitter for transmitting a first main signal S_{A}(t) and a second main signal S_{B}(t), the transmitter comprising:
a first antenna and a second antenna;
a first delay element for delaying the first main signal S_{A}(t) to produce a first delayed signal S_{A}(t-D1) where D1 is a first delay;
a second delay element for delaying the second main signal S_{B}(t) to produce a second delayed signal S_{B}(t-D2) where D2 is a second delay;
wherein a first linear combination of one of the main signals and one of the delayed signals is transmitted from the first antenna and a second linear combination of the other of the main signals and the other of the delayed signals is transmitted from the second antenna.

7. The transmitter according to claim 6 wherein the first main signal and the second main signal are each CDMA (Code Division Multiple Access) signals.

8. The transmitter according to claim 6 wherein the first linear combination comprises:
X_{A}(t)=α_{A1}S_{A}(t)+α_{A2}S_{A}(t-D1)
and the second linear combination comprises:
X_{B}(t)=α_{B1}S_{B}(t)+α_{B1}S_{B}(t-D2)
wherein α_{A1}, α_{A2}, α_{B1}, α_{B2} form a set of virtual spatial reflectors chosen such that a resulting channel matrix H yields a well conditioned H*H for a particular noise environment where D1 and D2 are delays and where H* is the complex conjugate of H.

9. The transmitter according to claim 6 wherein the first linear combination comprises:
X_{A}(t)=α_{A1}S_{A}(t)+α_{B2}S_{B}(t-D1)
and the second linear combination comprises:
X_{B}(t)=α_{B1}S_{B}(t)+α_{A2}S_{A}(t-D2)
wherein α_{A1}, α_{A2}, α_{B1}, α_{B2} form a set of virtual spatial reflectors chosen such that a resulting channel matrix H yields a well conditioned H*H for a particular noise environment where D1 and D 2 are delays and where H* is the complex conjugate of H.

10. The transmitter according to claim 7 further comprising:
a scrambling circuit for scrambling a first signal to produce the first main signal and for scrambling a second signal to produce the second main signal, the first signal and the second signal being scrambled with an identical scrambling code.

11. The transmitter according to claim 7 further comprising:
a scrambling circuit for scrambling a first signal to produce the first main signal and for scrambling a second signal to produce the second main signal, the first signal and the second signal being scrambled with different scrambling codes.

12. The transmitter according to claim 11 wherein each delay implemented in one of the delay elements is selected to provide enough separation between the scrambling code and a version of the scrambling code delayed by the delay such that the scrambling code and the scrambling code delayed by the delay are substantially orthogonal to each other.

13. The transmitter according to claim 11 further comprising:
a demultiplexer for splitting a symbol stream into symbols included in said first signal and said second signal.

14. The transmitter according to claim 6 adapted to transmit from each antenna a respective CDMA (Code Division Multiple Access) signal containing a plurality of code separated channels, the plurality of code separated channels comprising:
a respective first set of at least one channels which are generic to multiple users;
a respective second set of at least one channels which are user specific; and
a respective third set of channels which are user specific and which function as one of said main signals.

15. The transmitter according to claim 6 wherein the first main signal and the second main signal are each OFDM (Orthogonal Frequency Division Modulation) signals.

16. The transmitter according to claim 15 wherein the first linear combination comprises:
X_{A}(t)=α_{A1}S_{A}(t)+α_{A2}S_{A}(t-D1)
and the second linear combination comprises:
X_{B}(t)=α_{B1}S_{B}(t)+α_{B2}S_{B}(t-D2)
wherein α_{A1}, α_{A2}, α_{B1}, α_{B2} form a set of virtual spatial reflectors chosen such that a resulting channel matrix H yields a well conditioned H*H for a particular noise environment and where D1 and D2 are delays and where H* is the complex conjugate of H.

17. The transmitter according to claim 15 wherein the first linear combination comprises:
X_{A}(t)=α_{A1}S_{A}(t)+α_{B2}S_{B}(t-D1)
and the second linear combination comprises:
X_{B}(t)=α_{B1}S_{B}(t)+α_{A2}S_{A}(t-D2)
wherein α_{A1}, α_{A2}, α_{B1}, α_{B2} form a set of virtual spatial reflectors chosen such that a resulting channel matrix H yields a well conditioned H*H for a particular noise environment and where H* is the complex conjugate of H.

18. The transmitter according to claim 15 further comprising:
a forward error correction block for performing forward error correction on an incoming bit stream to generate a coded bit stream;
a symbol mapping function for mapping the coded bit stream to a first modulation symbol stream;
a demultiplexing function adapted to divide the modulation symbol stream into second and third modulation symbol streams;
a first IFFT (Inverse Fast Fourier Transform) function, first prefix adding function and first windowing filter adapted to process the second modulation symbol stream to generate the first main signal;
a second IFFT (Inverse Fast Fourier Transform) function, second prefix adding function and second windowing filter adapted to process the third modulation symbol stream to generate the second main signal.

19. The transmitter according to claim 16 wherein α_{A1}, α_{A2}, α_{B1}, α_{B2} are chosen to optimize at least one of the following constraints:
a) balanced energy: |α_{A1}|²+|α_{A2}|²+|α_{A1}+α_{A2}|²=|α_{B1}|²+|α_{B2}|²+|α_{B1}+α_{B2}|²;
b) there is no large notch in frequency domain;
c) maximize capacity; and
d) meet a specified spectrum mask.

20. A receiver for receiving a signal transmitted over a wireless channel from a transmitter having a plurality N of transmit antennas, wherein the transmitter is adapted to transmit a respective one of N transmit signals from each of the N antennas, the N transmit signals collectively containing a plurality N of main signals and a plurality of delayed main signals each delayed main signal being a delayed version of one of the main signals, wherein each transmit signal comprises a combination of a respective main signal of the plurality of main signals and at least one respective delayed main signal of the N delayed main signals, the receiver comprising:
at least one receive antenna, each receive antenna receiving a respective receive signal over the wireless channel from the transmitter;
receive signal processing circuitry adapted to perform receive processing for each of the N main signals and each of the N delayed main signals.

21. The receiver of claim 20 wherein there are less than N receive antennas.

22. The receiver of claim 20 wherein there is only one receive antenna.

23. The receiver of claim 20 wherein all signals are CDMA (Code Division Multiple Access) signals.

24. The receiver of claim 23 wherein the receive signal processing circuitry comprises:
a finger detector configured to process each receive signal to identify multi-path components transmitted by each antenna, the multi-path components comprising at least one pair of multi-path components comprising a first multi-path component and a second multi-path component which is later than the first multi-path component by the delay introduced at the transmitter.

25. The receiver of claim 24 wherein the receive signal processing circuitry comprises de-scrambling and de-spreading functions which produce de-spread signals for each multi-path component, the receiver further comprising:
a virtual array processor for performing combining of the de-spread signals.

26. A receiver for receiving a signal transmitted over a wireless channel from a transmitter having a plurality N of transmit antennas, wherein the transmitter is adapted to transmit a respective one of N transmit signals from each of the N antennas, the N transmit signals collectively containing a plurality N of main signals and a plurality of delayed main signals each delayed main signal being a delayed version of one of the main signals, wherein each transmit signal comprises a combination of a respective main signal of the plurality of main signals and at least one respective delayed main signal of the N delayed main signals, the receiver comprising:
at least one receive antenna, each receive antenna receiving a respective receive signal over the wireless channel from the transmitter;
for each receive antenna, a respective over-sampling analog to digital converter which samples the respective receive signal and a respective sample selector adapted to produce a respective plurality of sample streams;
signal processing circuitry adapted to perform receive processing for each of the sample streams to produce pre-combined signals;
a MIMO (Multiple Input Multiple Output) decoder adapted to perform MIMO processing on the pre-combined signals.

27. The receiver of claim 26 wherein there are less than N receive antennas.

28. The receiver of claim 26 wherein there is only one receive antenna.

29. The receiver of claim 26 wherein each transmit signal comprises a main signal and N-1 delayed signals, and wherein each over-sampling analog to digital converter performs N times over-sampling.

30. The receiver of claim 28 wherein each transmit signal comprises one main signal and one delayed main signal, wherein two-times over-sampling is performed, and wherein the sample selector takes all even samples to generate a first of the sample streams, and takes all odd samples to generate a second of the sample streams.

31. A system comprising:
a transmitter according to claim 1;
a receiver comprising:
at least one receive antenna, each receive antenna receiving a respective receive signal over the wireless channel from the transmitter;
receive signal processing circuitry adapted to process the receive signals.

32. The system of claim 31 wherein the receive signal processing circuitry is adapted to perform receive processing for each of the N main signals and each of the N delayed main signals.

33. The system of claim 31 wherein the N transmit signals comprise a Jth transmit signal Transmit_{J} from antenna J=1, . . . , N, and wherein Transmit_{J} comprises:
$${Transmit}_{J} = {α}_{J} {T}_{J} ( {S}_{J} ) + {\sum }_{i = 1}^{{K}_{J}} {α}_{iJ} {T}_{i , J} ( {S}_{iJ} ( t - {D}_{iJ} ) )$$
S_{J}=is the Jth main signal of the plurality of main signals;
α_{J}=is a virtual spatial reflector applied to the Jth main signal;
T_{J}=is a transformation applied to the Jth main signal;
K_{J} is a number of delayed signals included in the Jth transmit signal;
α_{iJ}=is a virtual spatial reflector applied to the ith delayed signal included in the Jth transmit signal;
S_{iJ}, i=1, . . . , K_{J} are the signals which are to be delayed and included in the Jth transmit signal where each iJ ε 1, . . . , N;
D_{iJ}=is a delay applied to signal S_{iJ};
T_{iJ}=is a transformation applied to the ith delayed signal included in the Jth transmit signal.

34. The system of claim 32 adapted to transmit and receive CDMA (Code Division Multiple Access) signals.

35. The system of claim 34 wherein each main signal comprises a respective combined set of at least one code separated channel.

36. The system of claim 31 wherein there are two transmit signals, and the main signals comprise a first main signal S_{A}(t) and a second main signal S_{B}(t), the transmitter further comprising:
a first antenna and a second antenna;
a first delay element for delaying the first main signal S_{A}(t) to produce a first delayed signal S_{A}(t-D1) where D1 is a first delay;
a second delay element for delaying the second main signal S_{B}(t) to produce a second delayed signal S_{B}(t-D2) where D2 is a second delay;
wherein a first linear combination of one of the main signals and one of the delayed signals is transmitted from the first antenna and a second linear combination of the other of the main signals and the other of the delayed signals is transmitted from the second antenna.

37. The system of claim 31 wherein there are less than N receive antennas.

38. The system of claim 31 wherein there is only one receive antenna.

39. The system of claim 32 wherein the receive signal processing circuitry comprises:
a finger detector configured to process each receive signal to identify multi-path components transmitted by each antenna, the multi-path components comprising at least one pair of multi-path components comprising a first multi-path component and a second multi-path component which is later than the first multi-path component by the delay introduced at the transmitter.

40. The receiver of claim 39 wherein the receive signal processing circuitry comprises de-scrambling and de-spreading functions which produce de-spread signals for each multi-path component the receiver further comprising:
a virtual array processor for performing combining of the de-spread signals.

41. The system according to claim 31 adapted to transmit and receive OFDM (Orthogonal Frequency Division Modulation) signals.

42. The system according to claim 36 adapted to transmit and receive OFDM (Orthogonal Frequency Division Modulation) signals wherein the transmitter further comprises:
a forward error correction block for performing forward error correction on an incoming bit stream to generate a coded bit stream;
a symbol mapping function for mapping the coded bit stream to a first modulation symbol stream;
a demultiplexing function adapted to divide the modulation symbol stream into second and third modulation symbol streams;
a first IFFT (Inverse Fast Fourier Transform) function, first prefix adding function and first windowing filter adapted to process the second modulation symbol stream to generate the first main signal;
a second IFFT (Inverse Fast Fourier Transform) function, second prefix adding function and second windowing filter adapted to process the third modulation symbol stream to generate the second main signal.

43. The system according to claim 41 wherein the receiver comprises:
at least one receive antenna, each receive antenna receiving a respective receive signal over the wireless channel from the transmitter;
for each receive antenna, a respective over-sampling analog to digital converter which samples the respective signal and a respective sample selector adapted to produce a respective plurality of sample streams;
signal processing circuitry adapted to perform receive processing for each of the sample streams to produce pre-combined signals;
a MIMO (Multiple Input Multiple Output) decoder adapted to perform MIMO processing on the pre-combined signals.

44. The system of claim 43 wherein there are less than N receive antennas.

45. The system of claim 43 wherein there is only one receive antenna.

46. The system of claim 43 wherein each transmit signal comprises a main signal and N-1 delayed signals, and wherein each over-sampling analog to digital converter performs N times over-sampling.

47. The system of claim 45 wherein each transmit signal comprises one main signal and one delayed main signal, wherein two-times over-sampling is performed, and wherein the sample selector takes all even samples to generate a first of the sample streams, and takes all odd samples to generate a second of sample streams.

48. A method of transmitting comprising:
delaying each of N main signals by each of at least one respective delay to produce at least one respective delayed main signal;
transmitting from each of N>=2 antennas a respective signal comprising one of the main signals combined with at least one of the delayed main signals.

49. A method of receiving comprising:
at a single receive antenna, receiving over a wireless channel a received signal produced in accordance with the method of claim 48;
processing the received signal to produce at least two signals which are mathematically equivalent to two signals which would be received over two different receive antennas;
processing the two signals as if they were received over two different antennas.
